(19) United States
(12) Patent Application Publication
(10) Pub. No.: US 2025/0040245 A1
(43) Pub. Date: Jan. 30, 2025

(54) SEMICONDUCTOR DEVICE AND A METHOD OF MANUFACTURING THE SAME

(71) Applicant: SAMSUNG ELECTRONICS CO., LTD., Suwon-si (KR)

(72) Inventors: Suk YANG, Suwon-si (KR); Sung-Hwan JANG, Suwon-si (KR); Jinbum KIM, Suwon-si (KR); Sunguk JANG, Suwon-si (KR)

(73) Assignee: SAMSUNG ELECTRONICS CO., LTD., Suwon-si (KR)

(21) Appl. No.: 18/602,827

(22) Filed: Mar. 12, 2024

(30) Foreign Application Priority Data
Jul. 28, 2023 (KR) 10-2023-0099007

(51) Int. Cl. H01L 27/118

(52) U.S. Cl. CPC H01L 27/11807; H01L 2027/11853; H01L 2027/11874

(57) ABSTRACT

A semiconductor device includes a substrate, a first device region on the substrate, a second device region on the substrate and spaced apart from the first device region in a first direction, a first dummy region between the first device region and the second device region, and an insulating pattern in the first device region, the second device region and the first dummy region, where the first dummy region includes a seed pattern on the insulating pattern, and a seed mask pattern at least partially covering a top surface of the seed pattern and extending from the top surface of the seed pattern along a first sidewall of the seed pattern, where the insulating pattern in the first dummy region is on the substrate, and where the seed pattern includes a transition metal dichalcogenide.

### CROSS-REFERENCE TO RELATED APPLICATIONS

This application is based on and claims priority under 35 U.S.C. § 119 to Korean Patent Application No. 10-2023-0099007, filed on Jul. 28, 2023, in the Korean Intellectual Property Office, the disclosure of which is incorporated herein by reference in its entirety.

### BACKGROUND

Semiconductor devices may include integrated circuits including metal-oxide-semiconductor (MOS) field effect transistors (FETs) (MOSFETs). As sizes and design rules of semiconductor devices have been reduced, MOSFETs have been scaled down. However, operating characteristics of semiconductor devices may deteriorate due to the reduction in size of MOSFETs. Accordingly, methods for forming semiconductor devices which have excellent performance while overcoming limitations caused by high integration have been studied.

### SUMMARY

Example embodiments provide a semiconductor device with improved reliability, and a method of manufacturing the same.

According to an aspect of an example embodiment, a semiconductor device may include a substrate, a first device region on the substrate, a second device region on the substrate and spaced apart from the first device region in a first direction, a first dummy region between the first device region and the second device region, and an insulating pattern in the first device region, the second device region and the first dummy region, where the first dummy region includes a seed pattern on the insulating pattern, and a seed mask pattern at least partially covering a top surface of the seed pattern and extending from the top surface of the seed pattern along a first sidewall of the seed pattern, where the insulating pattern in the first dummy region is on the substrate, and where the seed pattern includes a transition metal dichalcogenide.

According to an aspect of an example embodiment, a semiconductor device may include a substrate, a first logic cell on the substrate, a second logic cell on the substrate and spaced apart from the first logic cell in a first direction, and a dummy region between the first logic cell and the second logic cell, where the first logic cell includes a first source/drain pattern and a first channel pattern connected to the first source/drain pattern, where the first channel pattern includes a plurality of semiconductor patterns vertically stacked and spaced apart from each other, where the dummy region includes an insulating pattern on the substrate, a seed pattern on the insulating pattern and a seed mask pattern at least partially covering a top surface of the seed pattern and a first sidewall of the seed pattern, and where the top surface of the seed pattern is a level that is higher than a level of a top surface of an uppermost semiconductor pattern of the plurality of semiconductor patterns.

According to an aspect of an example embodiment, a semiconductor device may include a substrate, a first device region on the substrate, a second device region on the substrate and spaced apart from the first device region in a first direction, a first dummy region between the first device region and the second device region, and an insulating pattern in the first device region, the second device region and the first dummy region, where the first dummy region includes a seed pattern provided on the insulating pattern, and a seed mask pattern at least partially covering a top surface of the seed pattern and extending from the top surface of the seed pattern along a first sidewall of the seed pattern, where each of the first device region and the second device region includes an active pattern on the substrate, where the insulating pattern in the first device region and the second device region is on respective active patterns of the first device region and the second device region, source/drain patterns on the insulating pattern, channel patterns on the insulating pattern and connected to the source/drain patterns, each of the channel patterns including a plurality of semiconductor patterns vertically stacked and spaced apart from each other, gate electrodes respectively on the channel patterns, the gate electrodes extending parallel to each other in a second direction that is perpendicular to the first direction, and active contacts respectively connected to the source/drain patterns, where the plurality of semiconductor patterns include a material that is the same as a material of the seed pattern, where the seed pattern includes a second sidewall opposite the first sidewall and that is exposed by the seed mask pattern, and where the second sidewall forms an acute angle with a top surface of the insulating pattern.

### BRIEF DESCRIPTION OF DRAWINGS

The above and other aspects, features, and advantages of certain example embodiments of the present disclosure will be more apparent from the following description taken in conjunction with the accompanying drawings, in which:

FIGS. 1, 2, and 3 are diagrams illustrating logic cells of semiconductor devices according to one or more example embodiments;

FIG. 4 is a plan view illustrating a semiconductor device according to one or more example embodiments;

FIGS. 5A, 5B, 5C, 5D and 5E are cross-sectional views taken along lines A-A′, B-B′, C-C′, D-D′ and E-E′ of FIG. 4, respectively, according to one or more example embodiments;

FIG. 6A is an enlarged view of a region ‘M’ of FIG. 5A according to one or more example embodiments;

FIGS. 6B and 6C are enlarged views of the region ‘M’ of FIG. 5A illustrating semiconductor devices according to one or more example embodiments;

FIG. 6D is an enlarged view of a region ‘N’ of FIG. 5A according to one or more example embodiments;

FIG. 6E is an enlarged view of a region ‘O’ of FIG. 5A according to one or more example embodiments;

FIGS. 7A to 12C are cross-sectional views illustrating a method of manufacturing a semiconductor device according to one or more example embodiments;

FIGS. 13 to 21 are diagrams illustrating a method of forming a structure of FIG. 7A according to one or more example embodiments; and

FIGS. 22A, 22B, 22C, 23A, 23B and 23C are diagrams illustrating methods of forming structures of FIGS. 6B and 6C, according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, the term “cover” may indicate a full covering or at least a partial covering of various components, as will be understood by one of ordinary skill in the art from the disclosure herein.

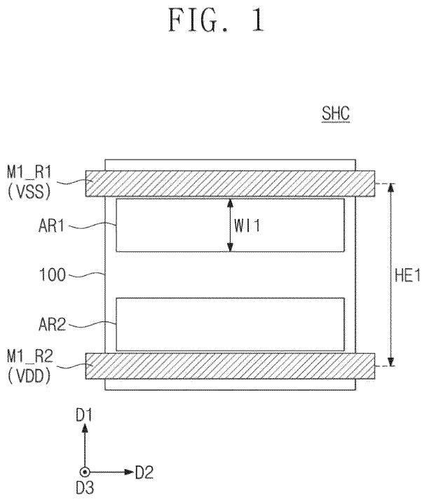

FIGS. 1, 2, and 3 are diagrams illustrating logic cells of semiconductor devices according to one or more example embodiments.

Referring to FIG. 1, a single height cell SHC may be provided. More particularly, a first power interconnection line M1_R1 and a second power interconnection line M1_R2 may be provided on a substrate 100. The first power interconnection line M1_R1 may be a path through which a source voltage (VSS, e.g., a ground voltage) is provided. The second power interconnection line M1_R2 may be a path through which a drain voltage (VDD, e.g., a power voltage) is provided.

The single height cell SHC may be defined between the first power interconnection line M1_R1 and the second power interconnection line M1_R2. The single height cell SHC may include a first active region AR1 and a second active region AR2. One of the first and second active regions AR1 and AR2 may be a p-type metal-oxide-semiconductor (MOS) field effect transistors (FETs) (MOSFETs) (PMOSFET) region, and the other of the first and second active regions AR1 and AR2 may be an n-type MOSFET (NMOSFET) region. In other words, the single height cell SHC may have a CMOS structure provided between the first power interconnection line M1_R1 and the second power interconnection line M1_R2. For example, the first active region AR1 may be the NMOSFET region, and the second active region AR2 may be the PMOSFET region.

Each of the first and second active regions AR1 and AR2 may have a single width WI1 in a first direction D1. A length of the single height cell SHC in the first direction D1 may be defined as a first height HE1. The first height HE1 may be substantially equal to a distance (e.g., a pitch) between the first power interconnection line M1_R1 and the second power interconnection line M1_R2.

The single height cell SHC may form a logic cell. The logic cell may refer to a logic element (e.g., an AND element, an OR element, an XOR element, an XNOR element, an inverter, etc.) for performing a specific function. In other words, the logic cell may include transistors and interconnection lines connecting the transistors to each other, which constitute the logic element.

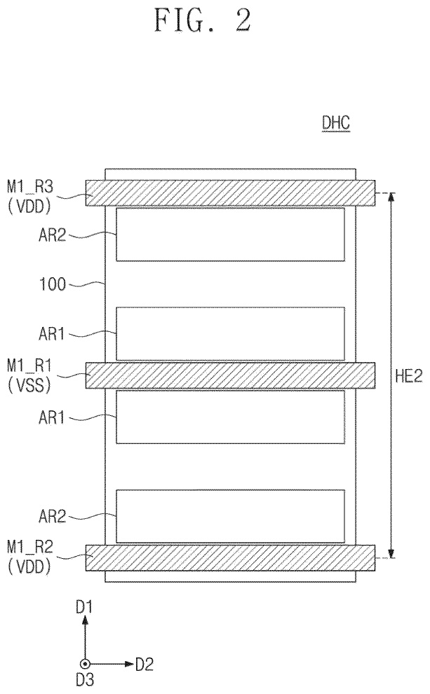

Referring to FIG. 2, a double height cell DHC may be provided. More particularly, a first power interconnection line M1_R1, a second power interconnection line M1_R2 and a third power interconnection line M1_R3 may be provided on a substrate 100. The first power interconnection line M1_R1 may be disposed between the second power interconnection line M1_R2 and the third power interconnection line M1_R3. The third power interconnection line M1_R3 may be a path through which a drain voltage VDD is provided.

The double height cell DHC may be defined between the second power interconnection line M1_R2 and the third power interconnection line M1_R3. The double height cell DHC may include two first active regions AR1 and two second active regions AR2.

One of the two second active regions AR2 may be disposed adjacent to the second power interconnection line M1_R2. The other of the two second active regions AR2 may be disposed adjacent to the third power interconnection line M1_R3. The two first active regions AR1 may be disposed adjacent to the first power interconnection line M1_R1. In a plan view, the first power interconnection line M1_R1 may be disposed between the two first active regions AR1.

A length of the double height cell DHC in the first direction D1 may be defined as a second height HE2. The second height HE2 may be about twice the first height HE1 of FIG. 1. The two first active regions AR1 of the double height cell DHC may be combined with each other to operate as a single active region.

The double height cell DHC shown in FIG. 2 may be defined as a multi-height cell. The multi-height cell may include a triple height cell of which a cell height is about three times that of the single height cell SHC.

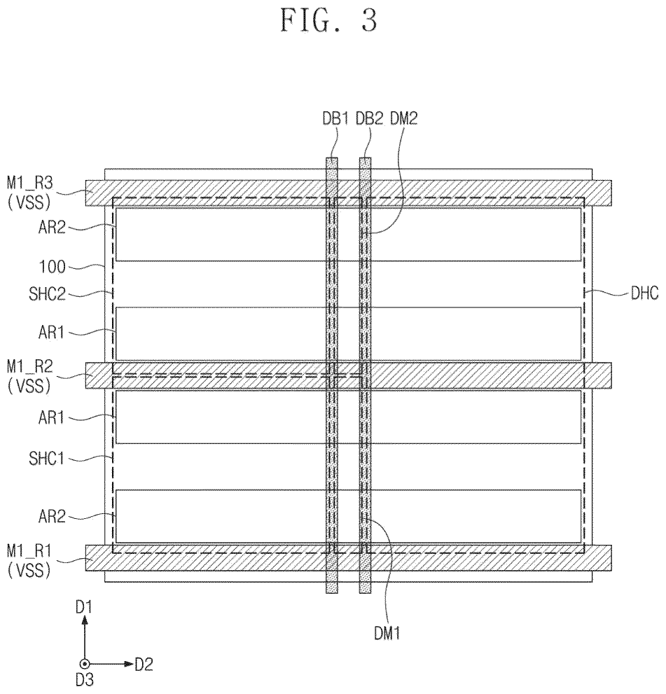

Referring to FIG. 3, a first single height cell SHC1, a second single height cell SHC2 and a double height cell DHC may be two-dimensionally arranged on a substrate 100. The first single height cell SHC1 may be disposed between the first and second power interconnection lines M1_R1 and M1_R2. The second single height cell SHC2 may be disposed between the first and third power interconnection lines M1_R1 and M1_R3. The second single height cell SHC2 may be adjacent to the first single height cell SHC1 in the first direction D1.

The double height cell DHC may be disposed between the second and third power interconnection lines M1_R2 and M1_R3. The double height cell DHC may be adjacent to the first and second single height cells SHC1 and SHC2 in a second direction D2.

A first dummy cell DM1 may be provided between the first single height cell SHC1 and the double height cell DHC. A second dummy cell DM2 may be provided between the second single height cell SHC2 and the double height cell DHC. The first dummy cell DM1 and the second dummy cell DM2 may be aligned with each other in the first direction D1.

The first and second dummy cells DM1 and DM2 may not include a logic element, unlike the logic cell. In other words, the first and second dummy cells DM1 and DM2 may not perform a circuit function.

As illustrated in FIG. 3, the first and second dummy cells DM1 and DM2 may be disposed between the logic cells SHC1, SHC2 and DHC in a cell region in which the logic cells SHC1, SHC2 and DHC are disposed. The arrangement of the first and second dummy cells DM1 and DM2 and the logic cells SHC1, SHC2 and DHC in FIG. 3 is illustrated as an example, but the arrangement of the logic cells and the dummy cells may be variously changed.

In some embodiments, a first isolation structure DB1 may be provided between the first dummy cell DM1 and the first single height cell SHC1 and between the second dummy cell DM2 and the second single height cell SHC2. A second isolation structure DB2 may be provided between the first dummy cell DM1 and the double height cell DHC and between the second dummy cell DM2 and the double height cell DHC. The active regions of the logic cells SHC1, SHC2 and DHC may be electrically isolated from active regions of the dummy cells DM1 and DM2 by the first and second isolation structures DB1 and DB2.

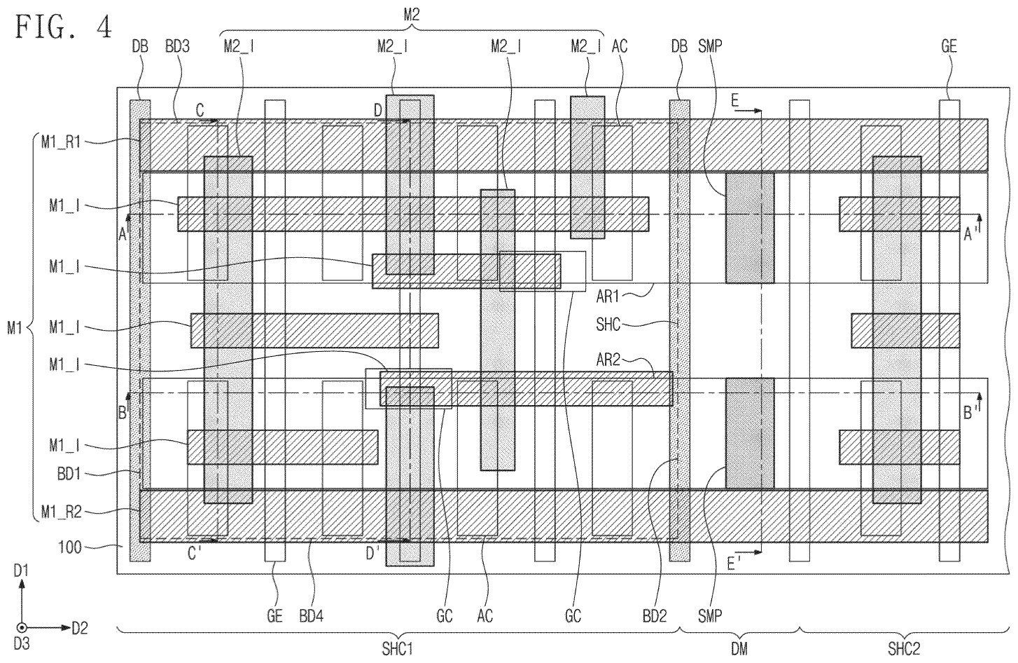

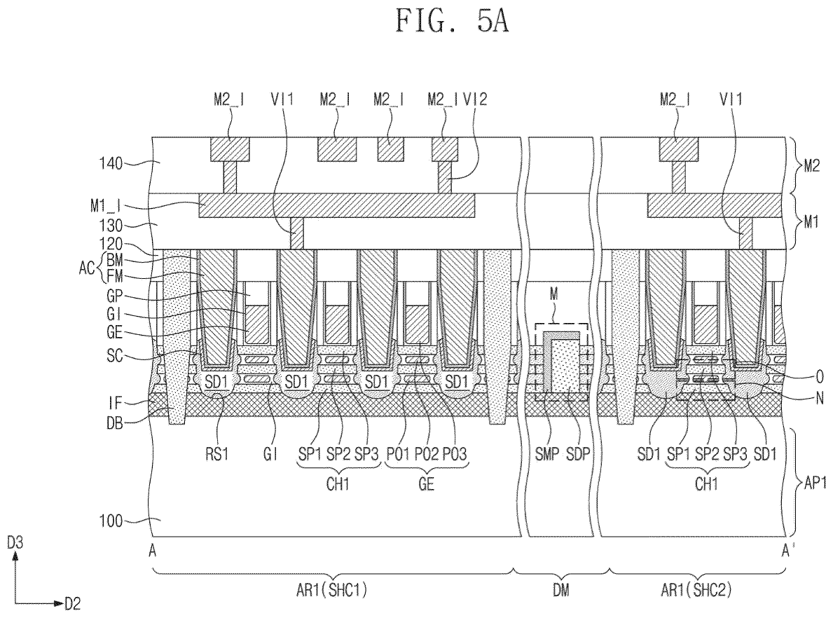

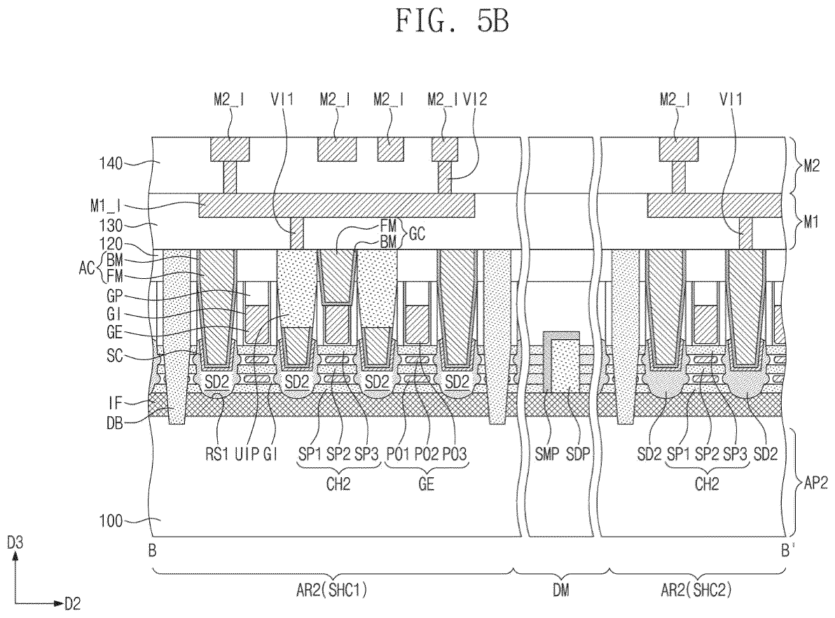

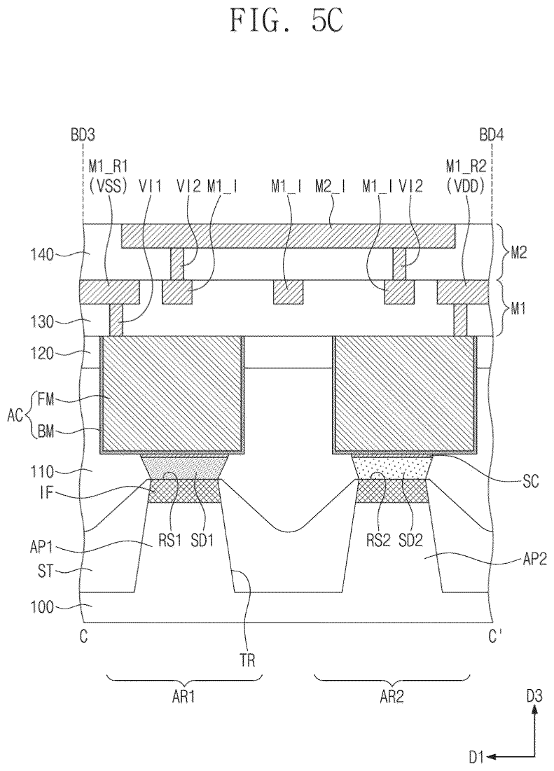

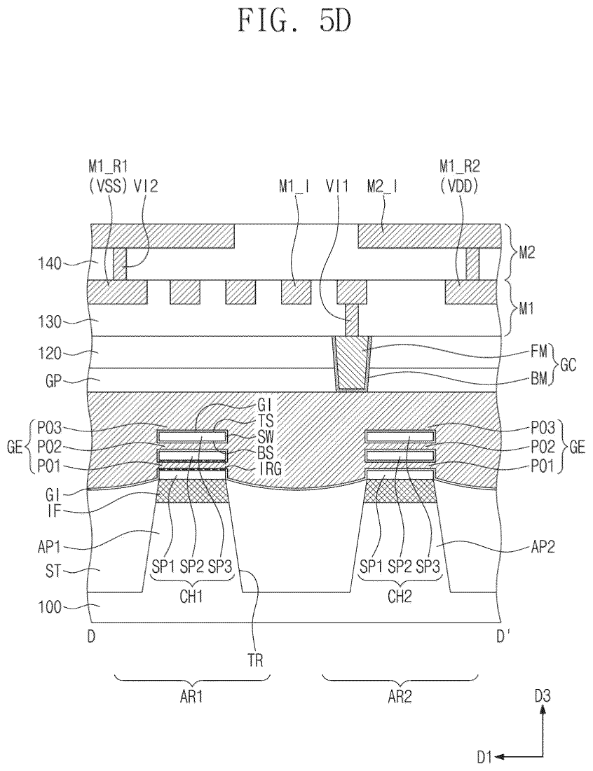

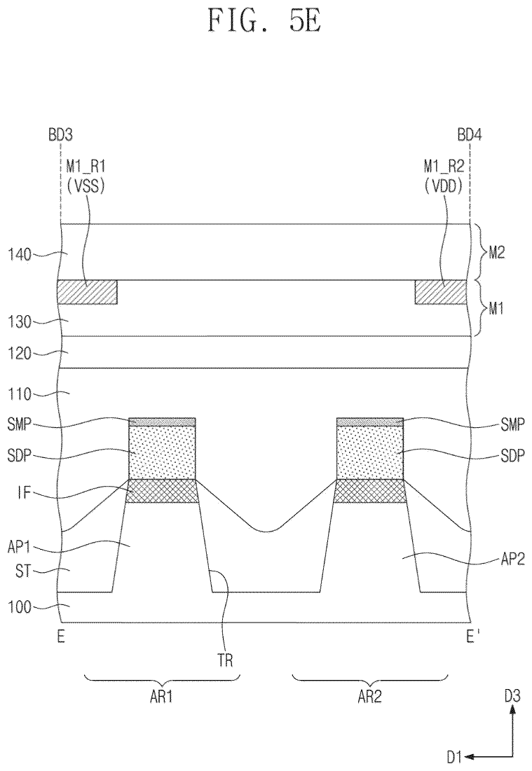

FIG. 4 is a plan view illustrating a semiconductor device according to one or more example embodiments. FIGS. 5A, 5B, 5C, 5D and 5E are cross-sectional views taken along lines A-A′, B-B′, C-C′, D-D′ and E-E′ of FIG. 4, respectively, according to one or more example embodiments. A semiconductor device of FIGS. 4 and 5A to 5E may include two single height cells and a dummy cell between the two single height cells.

Referring to FIGS. 4 and 5A to 5E, first and second single height cells SHC1 and SHC2 and a dummy cell DM may be provided on a substrate 100. The first single height cell SHC1 and the second single height cell SHC2 may be aligned with each other in the second direction D2. The dummy cell DM may be disposed between the first single height cell SHC1 and the second single height cell SHC2. Logic transistors constituting a logic circuit may be disposed on each of the first and second single height cells SHC1 and SHC2. Dummy transistors may be disposed on the dummy cell DM.

In some embodiments, the first single height cell SHC1 and the second single height cell SHC2 may be referred to as a first region and a second region, respectively. The dummy cell may be referred to as a dummy region.

The substrate 100 may be a semiconductor substrate including silicon, germanium or silicon-germanium, a compound semiconductor substrate, etc. For example, the substrate 100 may be a silicon substrate.

The substrate 100 may include a first active region AR1, a second active region AR2, and a dummy region DM. Each of the first and second active regions AR1 and AR2 may extend in the second direction D2. In some embodiments, the first active region AR1 may be an NMOSFET region, and the second active region AR2 may be a PMOSFET region. The dummy region DM may be included in the dummy cell DM.

A first active pattern AP1 and a second active pattern AP2 may be defined by a trench TR formed in an upper portion of the substrate 100. The first active pattern AP1 may be provided on the first active region AR1, and the second active pattern AP2 may be provided on the second active region AR2. The first and second active patterns AP1 and AP2 may extend in the second direction D2. The first and second active patterns AP1 and AP2 may be portions of the substrate 100, which vertically protrude.

An insulating pattern IF may be provided on each of the first and second active patterns AP1 and AP2. The insulating pattern IF may include an insulating material. For example, the insulating pattern IF may include at least one of SiO₂, SiN, SiCN, SiOC, and SiOCN. The insulating pattern IF may be formed to electrically insulate the substrate 100 from channel patterns CH1 and CH2 to be described below.

A device isolation layer ST may be provided on the substrate 100. The device isolation layer ST may fill the trench TR. The device isolation layer ST may include a silicon oxide layer. The device isolation layer ST may cover a sidewall of the insulating pattern IF. The device isolation layer ST may not cover first and second channel patterns CH1 and CH2 to be described below.

A first channel pattern CH1 may be provided on the first active pattern AP1. A second channel pattern CH2 may be provided on the second active pattern AP2. Each of the first channel pattern CH1 and the second channel pattern CH2 may include a first semiconductor pattern SP1, a second semiconductor pattern SP2 and a third semiconductor pattern SP3, which are sequentially stacked. The first to third semiconductor patterns SP1, SP2 and SP3 may be spaced apart from each other in a vertical direction (i.e., a third direction D3).

A plurality of first source/drain patterns SD1 may be provided on the first active pattern AP1. A plurality of first recesses RS1 may be formed on the first active pattern AP1. The first source/drain patterns SD1 may be provided in the first recesses RS1, respectively. The first source/drain patterns SD1 may be dopant regions having a first conductivity type (e.g., an n-type). The first channel pattern CH1 may be disposed between a pair of the first source/drain patterns SD1. In other words, the first to third semiconductor patterns SP1, SP2 and SP3 stacked sequentially may connect the pair of first source/drain patterns SD1 to each other.

A plurality of second source/drain patterns SD2 may be provided on the second active pattern AP2. A plurality of second recesses RS2 may be formed on the second active pattern AP2. The second source/drain patterns SD2 may be provided in the second recesses RS2, respectively. The second source/drain patterns SD2 may be dopant regions having a second conductivity type (e.g., a p-type). The second channel pattern CH2 may be disposed between a pair of the second source/drain patterns SD2. In other words, the first to third semiconductor patterns SP1, SP2 and SP3 stacked sequentially may connect the pair of second source/drain patterns SD2 to each other.

The first and second source/drain patterns SD1 and SD2 may be epitaxial patterns formed by a selective epitaxial growth (SEG) process. For example, a top surface of each of the first and second source/drain patterns SD1 and SD2 may be higher than a top surface of the third semiconductor pattern SP3. Alternatively, the top surface of at least one of the first and second source/drain patterns SD1 and SD2 may be located at substantially the same level as the top surface of the third semiconductor pattern SP3.

In some embodiments, the second source/drain patterns SD2 may include a semiconductor element (e.g., SiGe) having a lattice constant greater than a lattice constant of a semiconductor element of the substrate 100. Thus, the pair of second source/drain patterns SD2 may provide compressive stress to the second channel pattern CH2 therebetween. The first source/drain patterns SD1 may include the same semiconductor element (e.g., Si) as the substrate 100.

A sidewall of each of the first and second source/drain patterns SD1 and SD2 may have an uneven embossing shape. In other words, the sidewall of each of the first and second source/drain patterns SD1 and SD2 may have a wave-shaped profile. The sidewall of each of the first and second source/drain patterns SD1 and SD2 may protrude toward first to third portions PO1, PO2 and PO3 of a gate electrode GE to be described below.

Gate electrodes GE may extend in the first direction D1 to intersect the first and second channel patterns CH1 and CH2. The gate electrodes GE may be arranged in the second direction D2 at a first pitch. Each of the gate electrodes GE may be above the first and second channel patterns CH1 and CH2 in the third direction D3.

The gate electrode GE may include a first portion PO1 disposed between the first semiconductor pattern SP1 and the second semiconductor pattern SP2, a second portion PO2 disposed between the second semiconductor pattern SP2 and the third semiconductor pattern SP3, and a third portion PO3 on the third semiconductor pattern SP3.

Referring to FIG. 5D, the gate electrode GE may be provided on a top surface TS, a bottom surface BS and both sidewalls SW of each of the first to third semiconductor patterns SP1, SP2 and SP3. In other words, a transistor according to the present embodiments may be a three-dimensional field effect transistor (e.g., a MBCFET or a GAAFET) in which the gate electrode GE three-dimensionally surrounds a channel.

Referring again to FIGS. 4 and 5A to 5E, a pair of gate spacers GS may be disposed on both sidewalls of the third portion PO3 of the gate electrode GE, respectively. The gate spacers GS may extend along the gate electrode GE in the first direction D1. Top surfaces of the gate spacers GS may be higher than a top surface of the gate electrode GE. The top surfaces of the gate spacers GS may be coplanar with a top surface of a first interlayer insulating layer 110 to be described below. For example, the gate spacers GS may include at least one of SiCN, SiCON, and SiN. For certain examples, each of the gate spacers GS may include a multi-layer formed of at least two of SiCN, SiCON, or SiN.

A gate capping pattern GP may be provided on the gate electrode GE. The gate capping pattern GP may extend along the gate electrode GE in the first direction D1. The gate capping pattern GP may include a material having an etch selectivity with respect to first and second interlayer insulating layers 110 and 120 to be described below. For example, the gate capping pattern GP may include at least one of SiON, SiCN, SiCON, and SiN.

A gate insulating layer GI may be disposed between the gate electrode GE and the first channel pattern CH1 and between the gate electrode GE and the second channel pattern CH2. The gate insulating layer GI may cover the top surface and both sidewalls of the first semiconductor pattern SP1. The gate insulating layer GI may cover the top surface TS, the bottom surface BS and both sidewalls SW of each of the second and third semiconductor patterns SP2 and SP3. The gate insulating layer GI may cover a top surface of the device isolation layer ST under the gate electrode GE.

In some embodiments, the gate insulating layer GI may include a silicon oxide layer, a silicon oxynitride layer, and/or a high-k dielectric layer. The high-k dielectric layer may include a high-k dielectric material of which a dielectric constant is higher than that of a silicon oxide layer. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

In some embodiments, the semiconductor device may include a negative capacitance (NC) FET using a negative capacitor. For example, the gate insulating layer GI may include a ferroelectric material layer having ferroelectric properties, and a paraelectric material layer having paraelectric properties.

The ferroelectric material layer may have a negative capacitance, and the paraelectric material layer may have a positive capacitance. For example, when two or more capacitors are connected in series to each other and a capacitance of each of the capacitors has a positive value, a total capacitance may be reduced to be less than the capacitance of each of the capacitors. On the contrary, when at least one of capacitances of two or more capacitors connected in series to each other has a negative value, a total capacitance may have a positive value and may be greater than an absolute value of the capacitance of each of the capacitors.

When the ferroelectric material layer having the negative capacitance is connected in series to the paraelectric material layer having the positive capacitance, a total capacitance value of the ferroelectric and paraelectric material layers connected in series may increase. The transistor including the ferroelectric material layer may have a subthreshold swing (SS) less than 60 mV/decade at room temperature by using the increase in the total capacitance value.

The ferroelectric material layer may have the ferroelectric properties. For example, the ferroelectric material layer may include at least one of hafnium oxide, hafnium zirconium oxide, barium strontium titanium oxide, barium titanium oxide, and lead zirconium titanium oxide. In some examples, the hafnium zirconium oxide may be a material formed by doping hafnium oxide with zirconium (Zr). For certain examples, the hafnium zirconium oxide may be a compound of hafnium (Hf), zirconium (Zr) and oxygen (O).

The ferroelectric material layer may further include dopants doped therein. For example, the dopants may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). A kind of the dopants included in the ferroelectric material layer may be changed depending on a kind of the ferroelectric material included in the ferroelectric material layer.

When the ferroelectric material layer includes hafnium oxide, the dopants included in the ferroelectric material layer may include at least one of, for example, gadolinium (Gd), silicon (Si), zirconium (Zr), aluminum (Al), and yttrium (Y).

When the dopants are aluminum (Al), the ferroelectric material layer may include aluminum of 3 at % (atomic %) to 8 at %. A ratio of the dopants may be a ratio of the amount of aluminum to a sum of the amounts of hafnium and aluminum.

When the dopants are silicon (Si), the ferroelectric material layer may include silicon of 2 at % to 10 at %. When the dopants are yttrium (Y), the ferroelectric material layer may include yttrium of 2 at % to 10 at %. When the dopants are gadolinium (Gd), the ferroelectric material layer may include gadolinium of 1 at % to 7 at %. When the dopants are zirconium (Zr), the ferroelectric material layer may include zirconium of 50 at % to 80 at %.

The paraelectric material layer may have the paraelectric properties. For example, the paraelectric material layer may include at least one of silicon oxide or a metal oxide having a high-k dielectric constant. For example, the metal oxide included in the paraelectric material layer may include at least one of, but not limited to, hafnium oxide, zirconium oxide, and aluminum oxide.

The ferroelectric material layer and the paraelectric material layer may include the same material. The ferroelectric material layer may have the ferroelectric properties, but the paraelectric material layer may not have the ferroelectric properties. For example, when the ferroelectric material layer and the paraelectric material layer include hafnium oxide, a crystal structure of hafnium oxide included in the ferroelectric material layer may be different from a crystal structure of hafnium oxide included in the paraelectric material layer.

The ferroelectric material layer may have a thickness showing the ferroelectric properties. For example, the thickness of the ferroelectric material layer may range from 0.5 nm to 10 nm, but embodiments are not limited thereto. A critical thickness showing the ferroelectric properties may be changed depending on a kind of a ferroelectric material, and thus the thickness of the ferroelectric material layer may be changed depending on a kind of the ferroelectric material included therein.

For some examples, the gate insulating layer GI may include a single ferroelectric material layer. For other examples, the gate insulating layer GI may include a plurality of the ferroelectric material layers spaced apart from each other. The gate insulating layer GI may have a stack structure in which the ferroelectric material layers and the paraelectric material layers are alternately stacked.

Referring again to FIGS. 4 and 5A to 5E, the gate electrode GE may include a first metal pattern and a second metal pattern on the first metal pattern. The first metal pattern may be provided on the gate insulating layer GI and may be adjacent to the first to third semiconductor patterns SP1, SP2 and SP3. The first metal pattern may include a work function metal of adjusting a threshold voltage of a transistor. A desired threshold voltage of the transistor may be obtained by adjusting a thickness and a composition of the first metal pattern. For example, the first and second portions PO1 and PO2 of the gate electrode GE may be formed of the first metal pattern corresponding to the work function metal.

The first metal pattern may include a metal nitride layer. For example, the first metal pattern may include nitrogen (N) and at least one metal from among titanium (Ti), tantalum (Ta), aluminum (Al), tungsten (W), and molybdenum (Mo). In addition, the first metal pattern may further include carbon (C). In some embodiments, the first metal pattern may include a plurality of stacked work function metal layers.

The second metal pattern may include a metal having a resistance lower than that of the first metal pattern. For example, the second metal pattern may include at least one metal from among tungsten (W), aluminum (Al), titanium (Ti), and tantalum (Ta). For example, the third portion PO3 of the gate electrode GE may include the first metal pattern and the second metal pattern on the first metal pattern.

A first interlayer insulating layer 110 may be provided on the substrate 100. The first interlayer insulating layer 110 may cover the gate spacers GS and the first and second source/drain patterns SD1 and SD2. A top surface of the first interlayer insulating layer 110 may be substantially coplanar with the top surface of the gate capping pattern GP and the top surface of the gate spacer GS. A second interlayer insulating layer 120 covering the gate capping pattern GP may be disposed on the first interlayer insulating layer 110. A third interlayer insulating layer 130 may be provided on the second interlayer insulating layer 120. A fourth interlayer insulating layer 140 may be provided on the third interlayer insulating layer 130. For example, each of the first to fourth interlayer insulating layers 110 to 140 may include a silicon oxide layer.

Each of the first and second single height cells SHC1 and SHC2 may have a first boundary BD1 and a second boundary BD2, which are opposite to each other in the second direction D2. The first and second boundaries BD1 and BD2 may extend in the first direction D1. Each of the first and second single height cells SHC1 and SHC2 may have a third boundary BD3 and a fourth boundary BD4, which are opposite to each other in the first direction D1. The third and fourth boundaries BD3 and BD4 may extend in the second direction D2.

A pair of isolation structures DB opposite to each other in the second direction D2 may be provided at both sides of each of the first and second single height cells SHC1 and SHC2. For example, the pair of isolation structures DB may be provided on the first and second boundaries BD1 and BD2 of each of the first and second single height cells SHC1 and SHC2, respectively. The isolation structure DB may extend in the first direction D1 in parallel to the gate electrode GE. A pitch between the isolation structure DB and the gate electrode GE adjacent thereto may be equal to the first pitch.

The isolation structure DB may penetrate the first and second interlayer insulating layers 110 and 120 and may extend into the first and second active patterns AP1 and AP2. The isolation structure DB may penetrate an upper portion of each of the first and second active patterns AP1 and AP2. The isolation structure DB may electrically isolate the active region of each of the first and second single height cells SHC1 and SHC2 from an active region of another cell adjacent thereto.

Active contacts AC may penetrate the first and second interlayer insulating layers 110 and 120 so as to be electrically connected to the first and second source/drain patterns SD1 and SD2. A pair of the active contacts AC may be provided at both sides of the gate electrode GE, respectively. In a plan view, the active contact AC may have a bar shape extending in the first direction D1.

The active contact AC may be a self-aligned contact. In other words, the active contact AC may be formed to be self-aligned with the gate capping pattern GP and the gate spacer GS. For example, the active contact AC may cover at least a portion of a sidewall of the gate spacer GS. The active contact AC may cover a portion of the top surface of the gate capping pattern GP.

Metal-semiconductor compound layers SC (e.g., silicide layers) may be disposed between the active contact AC and the first source/drain pattern SD1 and between the active contact AC and the second source/drain pattern SD2, respectively. The active contact AC may be electrically connected to the source/drain pattern SD1 or SD2 through the metal-semiconductor compound layer SC. For example, the metal-semiconductor compound layer SC may include at least one of titanium silicide, tantalum silicide, tungsten silicide, nickel silicide, and cobalt silicide.

Gate contacts GC may penetrate the second interlayer insulating layer 120 and the gate capping patterns GP so as to be electrically connected to the gate electrodes GE, respectively. In a plan view, the gate contacts GC may overlap with the first active region AR1 and the second active region AR2, respectively. For example, the gate contact GC may be provided on the second active pattern AP2 (see FIG. 5D).

In some embodiments, referring to FIG. 5B, an upper portion of the active contact AC adjacent to the gate contact GC may be filled with an upper insulating pattern UIP. A bottom surface of the upper insulating pattern UIP may be lower than a bottom surface of the gate contact GC. In other words, a top surface of the active contact AC adjacent to the gate contact GC may be lower than the bottom surface of the gate contact GC due to the upper insulating pattern UIP. Thus, an electrical short between the gate contact GC and the active contact AC adjacent thereto may be prevented.

Each of the active contact AC and the gate contact GC may include a conductive pattern FM and a barrier pattern BM surrounding the conductive pattern FM. For example, the conductive pattern FM may include at least one metal of aluminum, copper, tungsten, molybdenum, and cobalt. The barrier pattern BM may cover sidewalls and a bottom surface of the conductive pattern FM. The barrier pattern BM may include a metal layer/a metal nitride layer. The metal layer may include at least one of titanium, tantalum, tungsten, nickel, cobalt, and platinum. The metal nitride layer may include at least one of a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

A first metal layer M1 may be provided in the third interlayer insulating layer 130. For example, the first metal layer M1 may include a first power interconnection line M1_R1, a second power interconnection line M1_R2, and first interconnection lines M1_I. The interconnection lines M1_R1, M1_R2 and M1_I of the first metal layer M1 may extend in the second direction D2 and be parallel to each other.

For example, the first and second power interconnection lines M1_R1 and M1_R2 may be provided on the third and fourth boundaries BD3 and BD4 of the first single height cell SHC1, respectively. The first power interconnection line M1_R1 may extend in the second direction D2 along the third boundary BD3. The second power interconnection line M1_R2 may extend in the second direction D2 along the fourth boundary BD4.

The first interconnection lines M1_I of the first metal layer M1 may be disposed between the first and second power interconnection lines M1_R1 and M1_R2. The first interconnection lines M1_I of the first metal layer M1 may be arranged in the first direction D1 at a second pitch. The second pitch may be less than the first pitch. A line width of each of the first interconnection lines M1_I may be less than a line width of each of the first and second power interconnection lines M1_R1 and M1_R2.

The first metal layer M1 may further include first vias VI1. The first vias VI1 may be provided under the interconnection lines M1_R1, M1_R2 and M1_I of the first metal layer M1. The active contact AC may be electrically connected to a corresponding one of the interconnection lines of the first metal layer M1 through a corresponding one of the first vias VI1. The gate contact GC may be electrically connected to a corresponding one of the interconnection lines of the first metal layer M1 through a corresponding one of the first vias VI1.

The interconnection line of the first metal layer M1 and the first via VI1 thereunder may be formed using different processes. In other words, each of the interconnection line and the first via VI1 of the first metal layer M1 may be formed using a single damascene process. The semiconductor device according to the present embodiments may be formed using processes less than 20 nm.

A second metal layer M2 may be provided in the fourth interlayer insulating layer 140. The second metal layer M2 may include a plurality of second interconnection lines M2_I. Each of the second interconnection lines M2_I of the second metal layer M2 may have a line shape or bar shape extending in the first direction D1. In other words, the second interconnection lines M2_I may extend in the first direction D1 in parallel to each other.

The second metal layer M2 may further include second vias VI2 provided under the second interconnection lines M2_I. The interconnection lines of the first metal layer M1 may be electrically connected to the interconnection lines of the second metal layer M2 through the second vias VI2. For example, the interconnection line of the second metal layer M2 and the second via VI2 thereunder may be formed together by a dual damascene process.

The interconnection lines of the first metal layer M1 and the interconnection lines of the second metal layer M2 may include the same conductive material or different conductive materials. For example, the interconnection lines of the first metal layer M1 and the interconnection lines of the second metal layer M2 may include at least one metal material among aluminum, copper, tungsten, molybdenum, ruthenium, and cobalt. Metal layers stacked on the fourth interlayer insulating layer 140 may be additionally provided. Each of the stacked metal layers may include interconnection lines for routing between cells.

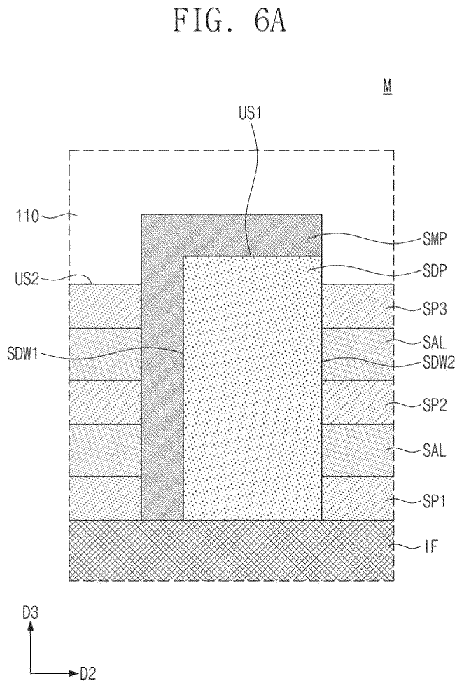

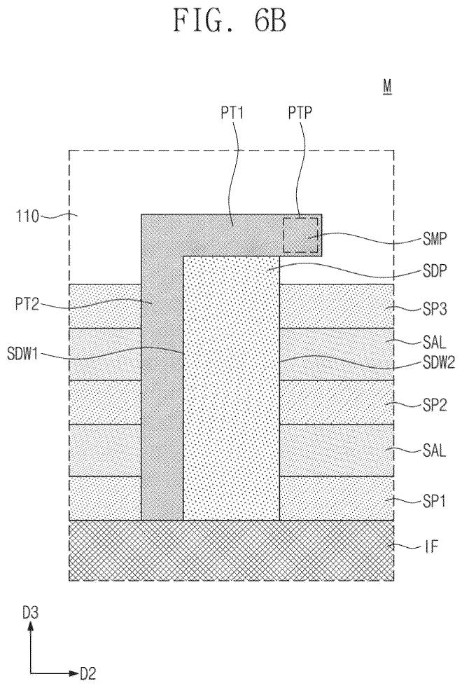

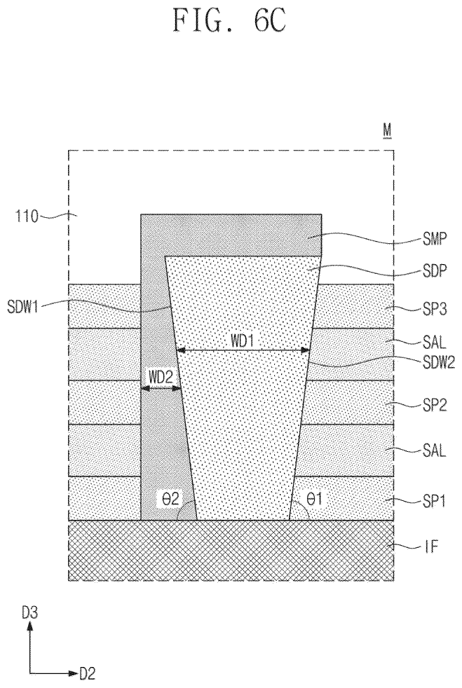

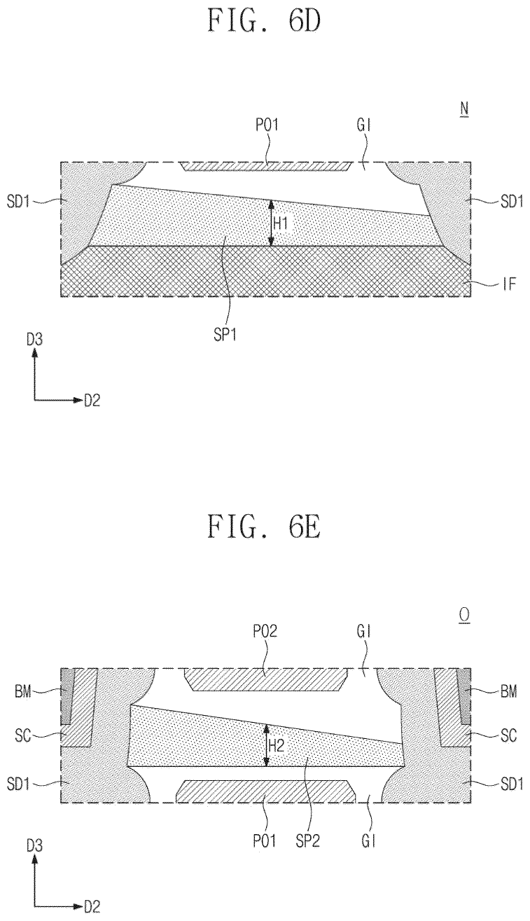

FIG. 6A is an enlarged view of a region ‘M’ of FIG. 5A according to one or more example embodiments. The dummy region DM will be described in more detail with reference to FIG. 6A.

Referring to FIGS. 4 and 6A, a seed pattern SDP and a seed mask pattern SMP may be provided on the insulating pattern IF. The seed pattern SDP may have a bar shape extending in the first direction D1. The seed pattern SDP may be above each of the first and second active patterns AP1 and AP2 in the third direction D3. In some embodiments, the first and second active patterns AP1 and AP2 located under the seed patterns SDP may be in the dummy regions.

The seed mask pattern SMP may cover a top surface US1 of the seed pattern SDP and may extend from the top surface US1 of the seed pattern SDP along one sidewall of the seed pattern SDP. In other words, the seed pattern SDP may have a first sidewall SDW1 covered by the seed mask pattern SMP, and a second sidewall SDW2 exposed by the seed mask pattern SMP. The first sidewall SDW1 and the second sidewall SDW2 may be opposite to each other in the second direction D2. The first sidewall SDW1 may be adjacent to the first single height cell SHC1, and the second sidewall SDW2 may be adjacent to the second single height cell SHC2 (see FIG. 5A).

The seed mask pattern SMP may include an insulating material. For example, the seed mask pattern SMP may include at least one of SiOₓ, SiN, SiCN, and SiCON. The seed pattern SDP may include a transition metal dichalcogenide. The first to third semiconductor patterns SP1 to SP3 may include the same material as the seed pattern SDP. This may be because the first to third semiconductor patterns SP1 to SP3 are grown from the seed pattern SDP in a manufacturing process to be described below. Thus, a thickness of each of the first to third semiconductor patterns SP1 to SP3 may not be uniform. For example, the thickness of each of the first to third semiconductor patterns SP1 to SP3 may progressively increase toward the second sidewall SDW2 of the seed pattern SDP.

The first to third semiconductor patterns SP1 to SP3 may be provided at one side or both sides of the seed pattern SDP. More particularly, the second sidewall SDW2 of the seed pattern SDP may contact the first to third semiconductor patterns SP1 to SP3 and sacrificial layers SAL. The sacrificial layers SAL may be used to form the gate electrode GE in a manufacturing method to be described below and may be provided between the first to third semiconductor patterns SP1 to SP3. For example, the sacrificial layers SAL may be provided between the first semiconductor pattern SP1 and the second semiconductor pattern SP2 and between the second semiconductor pattern SP2 and the third semiconductor pattern SP3, respectively.

The thickness of each of the first to third semiconductor patterns SP1 to SP3 may be less than a thickness of each of the sacrificial layers SAL. The sacrificial layers SAL may include a material having an etch selectivity with respect to the first to third semiconductor patterns SP1 to SP3. For example, the sacrificial layers SAL may include aluminum oxide (AlOₓ).

Each of the first to third semiconductor patterns SP1, SP2 and SP3 may include a transition metal dichalcogenide (TMD). The TMD may include a transition metal element and a chalcogen element. For example, the transition metal element may include at least one of tungsten, molybdenum, niobium, tantalum, hafnium, zirconium, gallium, manganese, vanadium, and rhenium. For example, the chalcogen element may include at least one of sulfur, selenium, or tellurium. Each of the first to third semiconductor patterns SP1 to SP3 may be a single-crystalline TMD layer.

In some embodiments, the first to third semiconductor patterns SP1, SP2 and SP3 may be stacked nanosheets. The first semiconductor pattern SP1 may be a lowermost semiconductor pattern, and the third semiconductor pattern SP3 may be an uppermost semiconductor pattern. A bottom surface of the first semiconductor pattern SP1 may directly contact a top surface of the insulating pattern IF.

The top surface US1 of the seed pattern SDP may be located at a higher level than a top surface US2 of the third semiconductor pattern SP3. This may be because the first to third semiconductor patterns SP1 to SP3 are grown from the seed pattern SDP in a manufacturing process to be described below. The top surface US1 of the seed pattern SDP may be located at the same level as the top surface US2 of the third semiconductor pattern SP3. A top surface of the seed mask pattern SMP may be located at a higher level than the top surface US2 of the third semiconductor pattern SP3.

The first interlayer insulating layer 110 may be formed on the seed mask pattern SMP and the third semiconductor pattern SP3. In the case in which the top surface US1 of the seed pattern SDP is higher than the top surface US2 of the third semiconductor pattern SP3, a portion of the second sidewall SDW2 of the seed pattern SDP may be in contact with the first interlayer insulating layer 110.

FIGS. 6B and 6C are enlarged views of the region ‘M’ of FIG. 5A to illustrate semiconductor devices according to one or more example embodiments.

Referring to FIG. 6B, the seed mask pattern SMP may include a first upper portion PT1 covering the top surface of the seed pattern SDP, and a first lower portion PT2 covering the first sidewall SDW1 of the seed pattern SDP. The first upper portion PT1 may include a protrusion PTP extending along the top surface of the seed pattern SDP to protrude in the second direction D2. The protrusion PTP may not cover the top surface of the seed pattern SDP (i.e., the protrusion PTP may extend over an edge of the top surface of the seed pattern SDP).

The first upper portion PT1 may have a first width in the second direction D2. The first width may be greater than a maximum width of the seed pattern SDP in the second direction D2. The first interlayer insulating layer 110 may be formed on a top surface, a bottom surface and a protruding sidewall of the protrusion PTP. The bottom surface of the protrusion PTP may be directly contact a portion of the top surface of the third semiconductor pattern SP3.

Referring to FIG. 6C, a first angle θ1 between a second sidewall SDW2 of the seed pattern SDP and the top surface of the insulating pattern IF may be an acute angle. A second angle θ2 between a first sidewall SDW1 of the seed pattern SDP and the top surface of the insulating pattern IF may be an acute angle. Thus, a width WD1 of the seed pattern SDP in the second direction D2 may progressively decrease toward the insulating pattern IF. On the contrary, a width WD2 of the first lower portion PT2 of the seed mask pattern SMP may progressively increase toward the insulating pattern IF.

FIG. 6D is an enlarged view of a region ‘N’ of FIG. 5A according to one or more example embodiments. FIG. 6E is an enlarged view of a region ‘O’ of FIG. 5A according to one or more example embodiments. FIGS. 6D and 6E are enlarged views illustrating the first channel pattern CH1 of the second single height cell SHC2 adjacent to the second sidewall SDW2 of the seed pattern SDP.

Referring to FIGS. 6D and 6E, a thickness H1 or H2 of each of the first and second semiconductor patterns SP1 and SP2 of the first channel pattern CH1 may decrease along the second direction D2. A thickness of the third semiconductor pattern SP3 may also decrease along the second direction D2, like the first and second semiconductor patterns SP1 and SP2. In other words, the thickness of each of the semiconductor patterns SP1 to SP3 may progressively increase toward the second sidewall SDW2 of the seed pattern SDP. This may be because each of the semiconductor patterns SP1 to SP3 may be grown from the seed pattern SDP in a manufacturing process to be described below. Since the thickness of each of the semiconductor patterns SP1 to SP3 decreases toward the second direction D2, a bottom surface of the gate insulating layer GI on each of the semiconductor patterns SP1 to SP3 may have a negative gradient.

If the seed mask pattern SMP is omitted, crystals of grown active layers ACL may meet each other to form a grain boundary. In addition, the active layers ACL may not be completely grown but may be grown in a specific region. These limitations may deteriorate electrical characteristics of a semiconductor device.

However, according to the embodiments of the disclosure, the first and second channel patterns CH1 and CH2 may be formed to be grown from the seed patterns SDP. Since the top surface and the first sidewall SDW1 of the seed pattern SDP are covered by the seed mask pattern SMP, the channel pattern may be formed to be grown from the seed pattern SDP in a single direction. Thus, each of the semiconductor patterns SP1 to SP3 may be a single-crystalline layer and may be formed to have a desired size and a desired shape in a desired region. As a result, electrical characteristics of the semiconductor device may be improved.

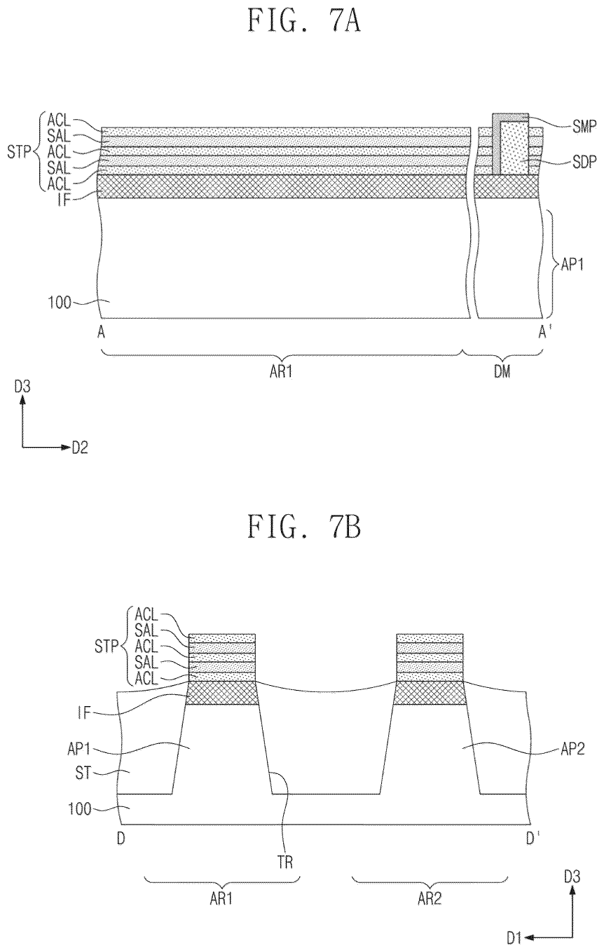

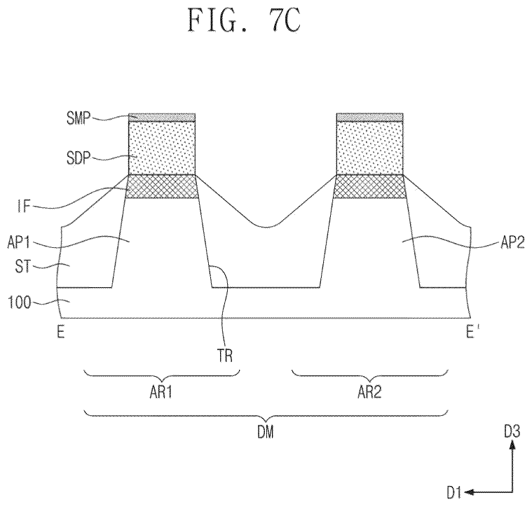

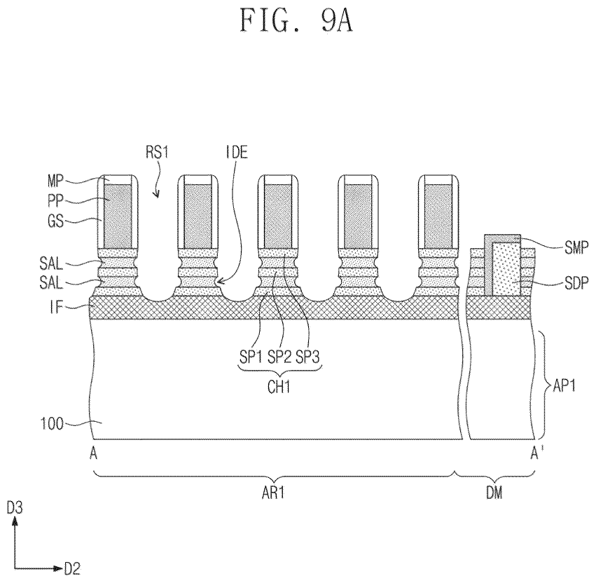

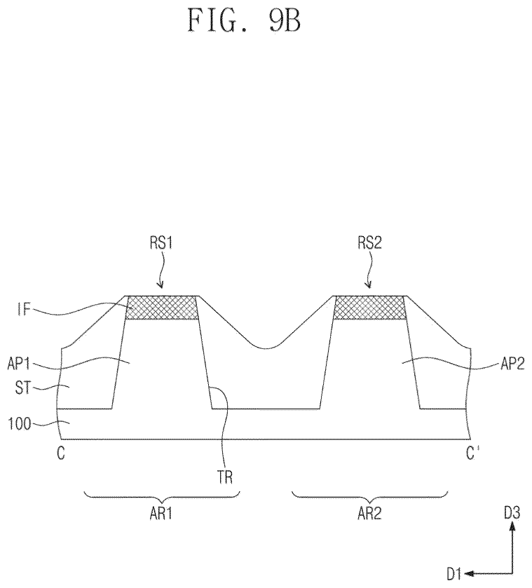

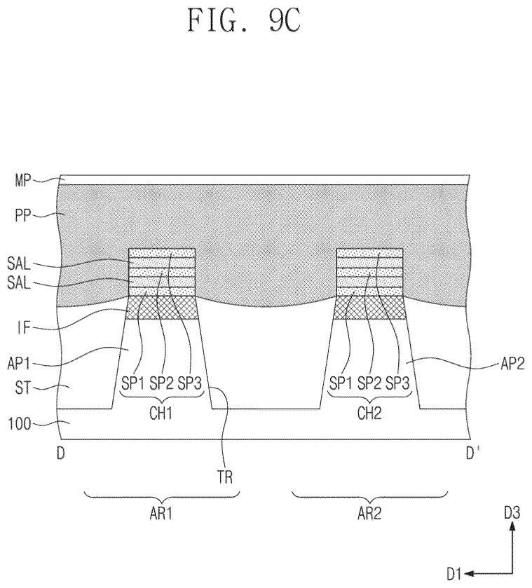

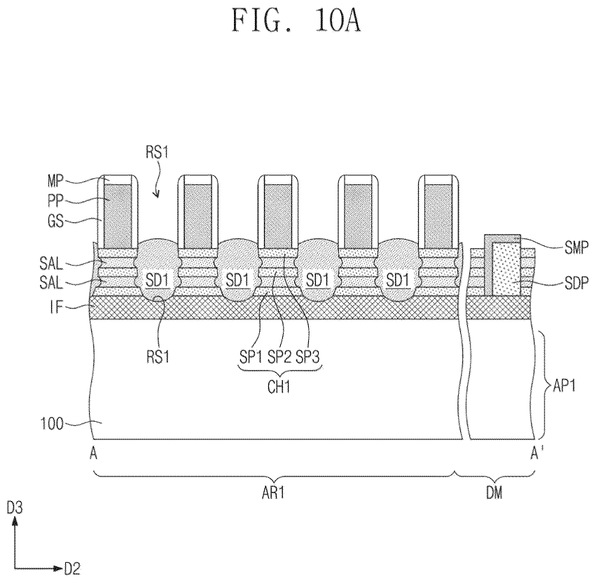

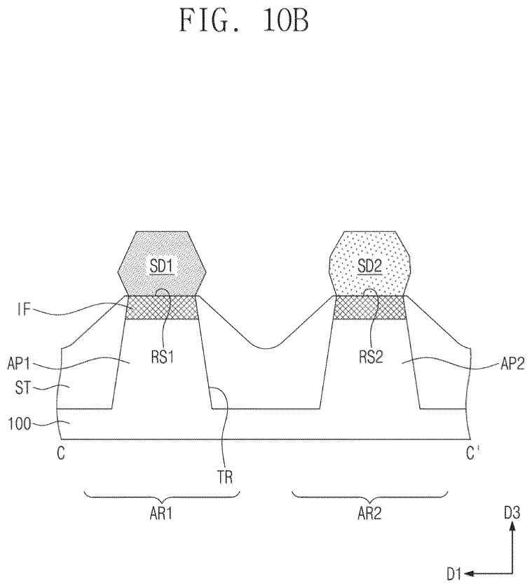

FIGS. 7A to 12C are cross-sectional views illustrating a method of manufacturing a semiconductor device according to one or more example embodiments. More particularly, FIGS. 7A, 8A, 9A, 10A, 11A and 12A are cross-sectional views corresponding to the line A-A′ of FIG. 4. FIGS. 9B, 10B, 11B and 12B are cross-sectional views corresponding to the line C-C′ of FIG. 4. FIGS. 7B, 8B, 9C, 10C, 11C and 12C are cross-sectional views corresponding to the line D-D′ of FIG. 4. FIG. 7C is a cross-sectional view corresponding to the line E-E′ of FIG. 4.

Referring to FIGS. 7A, 7B and 7C, a substrate 100 including first and second active regions AR1 and AR2 and a dummy region DM may be provided. An insulating pattern IF may be formed on an entire top surface of the substrate 100. The insulating pattern IF may include an insulating material. For example, the insulating pattern IF may include at least one of SiO₂, SiN, SiCN, SiOC, and SiOCN. Active layers ACL and sacrificial layers SAL may be formed to be alternately stacked on the substrate 100.

The active layers ACL may include a TMD. The sacrificial layers SAL may include a material having an etch selectivity with respect to the active layers ACL. For example, the sacrificial layers SAL may include aluminum oxide (AlO).

A seed pattern SDP and a seed mask pattern SMP covering a top surface and a sidewall of the seed pattern SDP may be formed on the dummy region DM. The seed pattern SDP may include a TMD. The seed pattern SDP and the active layers ACL may include the same material. The active layers ACL may be grown from the seed pattern SDP, and this will be described below. A top surface of the seed pattern SDP may be located at the same level as or a higher level than a top surface of an uppermost active layer ACL.

Mask layers may be formed on the first and second active regions AR1 and AR2 of the substrate 100, respectively. Each of the mask layers may have a line shape or bar shape extending in the second direction D2.

A patterning process may be performed using the mask layers as etch masks to form a trench TR defining a first active pattern AP1 and a second active pattern AP2. The first active pattern AP1 may be formed on the first active region AR1. The second active pattern AP2 may be formed on the second active region AR2.

A stack pattern STP may be formed on each of the first and second active patterns AP1 and AP2. The stack pattern STP may include the active layers ACL and the sacrificial layers SAL, which are alternately stacked. The stack patterns STP may be formed together with the first and second active patterns AP1 and AP2 in the patterning process.

A device isolation layer ST filling the trench TR may be formed. For example, an insulating layer covering the first and second active patterns AP1 and AP2, the insulating pattern IF and the stack patterns STP may be formed on an entire top surface of the substrate 100. The insulating layer may be recessed until the stack patterns STP are exposed, thereby forming the device isolation layer ST.

The device isolation layer ST may include an insulating material (e.g., silicon oxide). The stack patterns STP may be exposed above the device isolation layer ST. In other words, the stack patterns STP may vertically protrude above the device isolation layer ST.

Referring to FIG. 7C, the seed pattern SDP and the seed mask pattern SMP may be formed on the insulating pattern IF. The seed mask pattern SMP may cover the top surface of the seed pattern SDP.

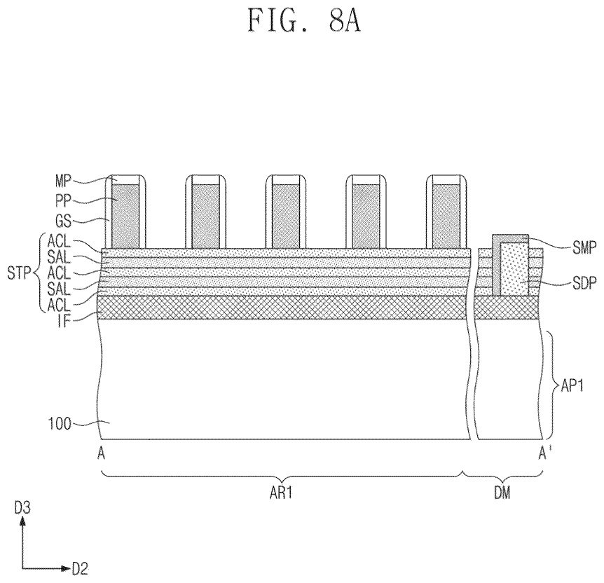

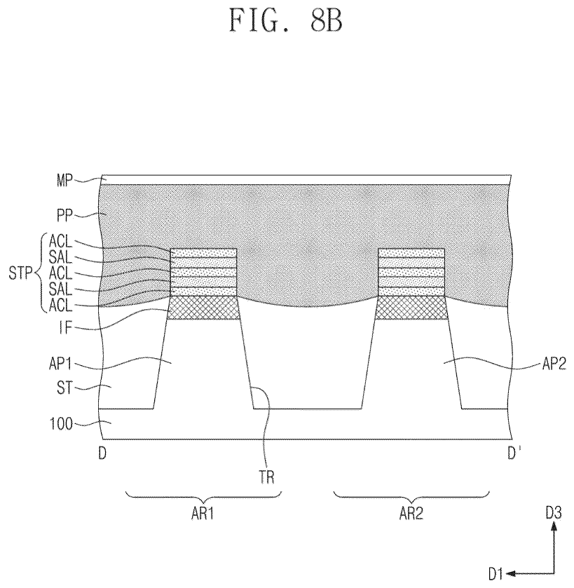

Referring to FIGS. 8A and 8B, sacrificial patterns PP intersecting the stack patterns STP may be formed on the substrate 100. Each of the sacrificial patterns PP may be formed to have a line shape or bar shape extending in the first direction D1. The sacrificial patterns PP may be arranged at a first pitch in the second direction D2. The sacrificial patterns PP may not be provided on the dummy region DM.

For example, the formation of the sacrificial patterns PP may include forming a sacrificial layer on an entire top surface of the substrate 100, forming hard mask patterns MP on the sacrificial layer, and patterning the sacrificial layer using the hard mask patterns MP as etch masks. The sacrificial layer may include poly-silicon.

A pair of gate spacers GS may be formed on both sidewalls of each of the sacrificial patterns PP, respectively. The formation of the gate spacers GS may include conformally forming a gate spacer layer on an entire top surface of the substrate 100, and anisotropically etching the gate spacer layer. In some embodiments, the gate spacer GS may be formed of a multi-layer including at least two layers.

Referring to FIGS. 9A to 9C, first recesses RS1 may be formed in the stack pattern STP on the first active pattern AP1. Second recesses RS2 may be formed in the stack pattern STP on the second active pattern AP2. Portions of an upper portion of the insulating pattern IF may be recessed when the first and second recesses RS1 and RS2 are formed. The device isolation layer ST at both sides of each of the first and second active patterns AP1 and AP2 may be further recessed during the formation of the first and second recesses RS1 and RS2 (see FIG. 9B).

More particularly, the stack pattern STP on the first active pattern AP1 may be etched using the hard mask patterns MP and the gate spacers GS as etch masks to form the first recesses RS1. The first recess RS1 may be formed between a pair of the sacrificial patterns PP. The formation of the first recess RS1 may include additionally performing a selective etching process on the exposed sacrificial layers SAL. Each of the sacrificial layers SAL may be indented by the selective etching process to form an indent region IDE. Thus, the first recess RS1 may have a wave-shaped inner sidewall. The second recesses RS2 in the stack pattern STP on the second active pattern AP2 may be formed by the same method as the first recesses RS1.

First to third semiconductor patterns SP1, SP2 and SP3 sequentially stacked between the first recesses RS1 adjacent to each other may be formed from the active layers ACL, respectively. The first to third semiconductor patterns SP1, SP2 and SP3 between the first recesses RS1 adjacent to each other may constitute a first channel pattern CH1. The first to third semiconductor patterns SP1, SP2 and SP3 between the second recesses RS2 adjacent to each other may constitute a second channel pattern CH2.

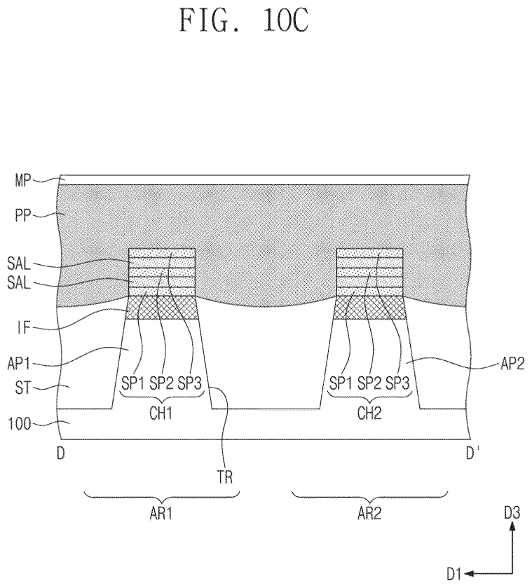

Referring to FIGS. 10A to 10C, first source/drain patterns SD1 may be formed in the first recesses RS1, respectively. For example, a SEG process using the inner sidewall of the first recess RS1 as a seed layer may be performed to form an epitaxial layer filling the first recess RS1. The epitaxial layer may be grown using the first to third semiconductor patterns SP1, SP2 and SP3 exposed by the first recess RS1 as seeds. For example, the SEG process may include a chemical vapor deposition (CVD) process or a molecular beam epitaxy (MBE) process.

Second source/drain patterns SD2 may be formed in the second recesses RS2, respectively. For example, the second source/drain pattern SD2 may be formed by performing a SEG process using an inner sidewall of the second recess RS2 as a seed layer.

In some embodiments, the second source/drain pattern SD2 may include a semiconductor element (e.g., SiGe) having a lattice constant greater than a lattice constant of a semiconductor element of the substrate 100. During the formation of the second source/drain pattern SD2, dopants (e.g., boron, gallium or indium) may be injected in-situ to allow the second source/drain pattern SD2 to have a p-type. Alternatively, after the formation of the second source/drain pattern SD2, the dopants may be injected or implanted into the second source/drain pattern SD2.

In some embodiments, the first source/drain pattern SD1 may include the same semiconductor element (e.g., Si) as the substrate 100. During the formation of the first source/drain pattern SD1, dopants (e.g., phosphorus, arsenic or antimony) may be injected in-situ to allow the first source/drain pattern SD1 to have an n-type. Alternatively, after the formation of the first source/drain pattern SD1, the dopants may be injected or implanted into the first source/drain pattern SD1.

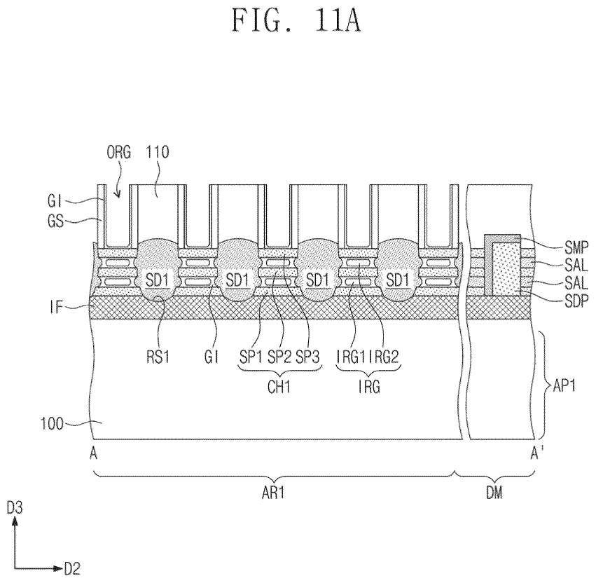

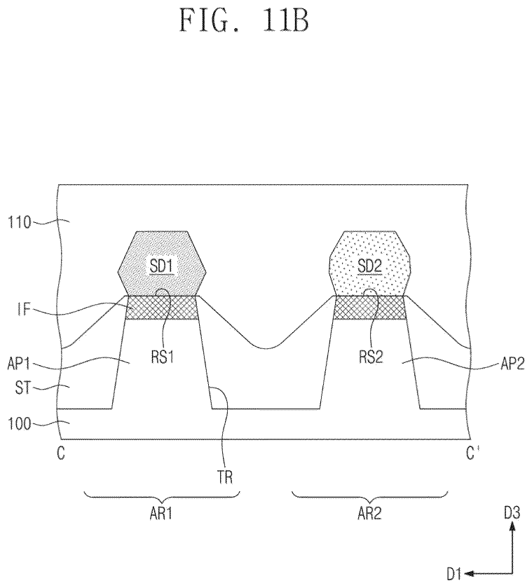

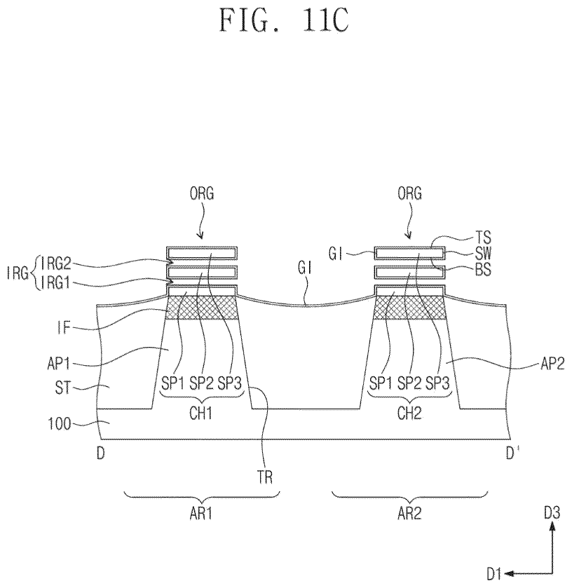

Referring to FIGS. 11A to 11C, a first interlayer insulating layer 110 may be formed to cover the first and second source/drain patterns SD1 and SD2, the hard mask patterns MP and the gate spacers GS. For example, the first interlayer insulating layer 110 may include a silicon oxide layer. The first interlayer insulating layer 110 may cover the dummy region DM. The first interlayer insulating layer 110 may cover the seed pattern SDP and the seed mask pattern SMP.

The first interlayer insulating layer 110 may be planarized to expose top surfaces of the sacrificial patterns PP. The planarization of the first interlayer insulating layer 110 may be performed using an etch-back process or a chemical mechanical polishing (CMP) process. The hard mask patterns MP may be completely removed during the planarization process. As a result, a top surface of the first interlayer insulating layer 110 may be substantially coplanar with the top surfaces of the sacrificial patterns PP and top surfaces of the gate spacers GS.

The exposed sacrificial patterns PP may be selectively removed. An outer region ORG exposing the first and second channel patterns CH1 and CH2 may be formed by the removal of the sacrificial pattern PP (see FIG. 11C). The removal of the sacrificial patterns PP may include performing a wet etching process using an etching solution capable of selectively etching poly-silicon.

The sacrificial layers SAL exposed through the outer region ORG may be selectively removed to form inner regions IRG (see FIG. 11C). For example, an etching process of selectively etching the sacrificial layers SAL may be performed to remove the sacrificial layers SAL while leaving the first to third semiconductor patterns SP1, SP2 and SP3. For example, the etching process may have a high etch rate with respect to aluminum oxide (AlO).

The sacrificial layers SAL on the first and second active regions AR1 and AR2 may be removed during the etching process. The etching process may be a wet etching process. An etching material used in the etching process may quickly remove the sacrificial layer SAL including aluminum oxide (AlO).

Referring again to FIG. 11C, since the sacrificial layers SAL are selectively removed, the stacked first to third semiconductor patterns SP1, SP2 and SP3 may remain on each of the first and second active patterns AP1 and AP2. First and second inner regions IRG1 and IRG2 may be formed by the removal of the sacrificial layers SAL.

For example, the first inner region IRG1 may be formed between the first semiconductor pattern SP1 and the second semiconductor pattern SP2, and the second inner region IRG2 may be formed between the second semiconductor pattern SP2 and the third semiconductor pattern SP3.

Referring again to FIGS. 11A to 11C, a gate insulating layer GI may be formed on the exposed first to third semiconductor patterns SP1, SP2 and SP3. The gate insulating layer GI may cover a top surface and both sidewalls of the first semiconductor pattern SP1. The gate insulating layer GI may surround each of the second and third semiconductor patterns SP2 and SP3. The gate insulating layer GI may be formed in each of the first and second inner regions IRG1 and IRG2. The gate insulating layer GI may be formed in the outer region ORG.

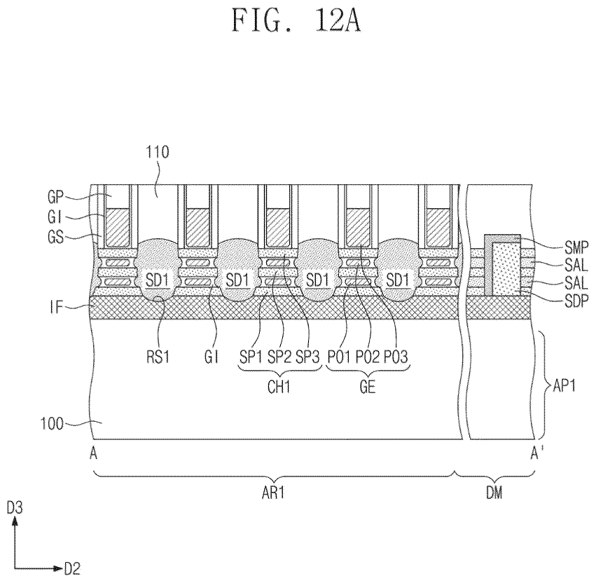

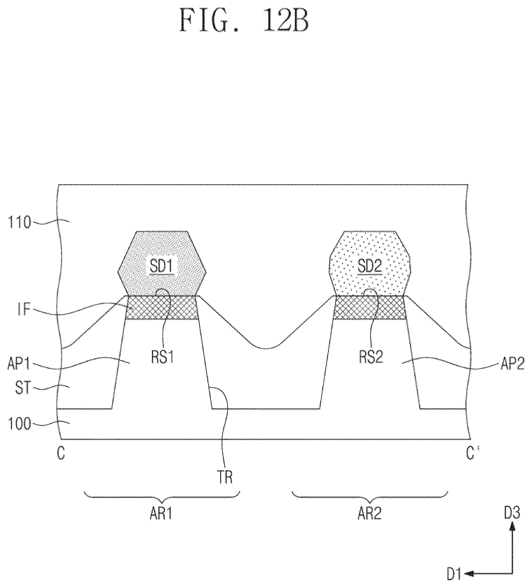

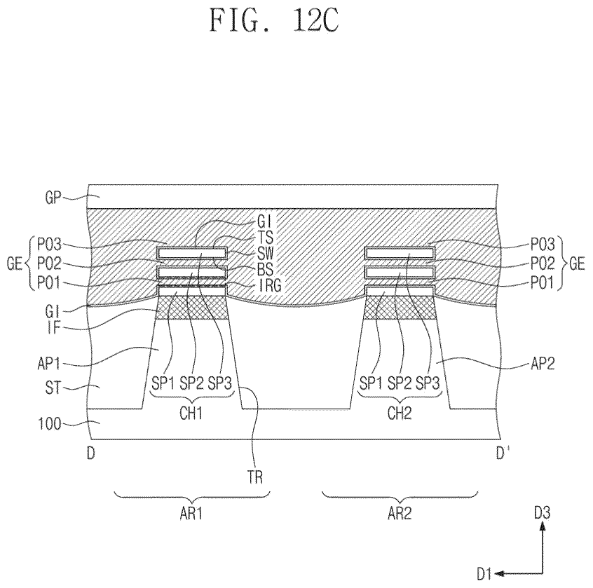

Referring to FIGS. 12A to 12C, a gate electrode GE may be formed on the gate insulating layer GI. The gate electrode GE may include first and second portions PO1 and PO2 formed in the first and second inner regions IRG1 and IRG2, respectively, and a third portion PO3 formed in the outer region ORG. The gate electrode GE may be recessed to reduce its height. A gate capping pattern GP may be formed on the recessed gate electrode GE. The gate electrode GE may not be formed on the dummy region DM.

Referring again to FIGS. 5A to 5E, a second interlayer insulating layer 120 may be formed on the first interlayer insulating layer 110. The second interlayer insulating layer 120 may include a silicon oxide layer. Active contacts AC may be formed to penetrate the second interlayer insulating layer 120 and the first interlayer insulating layer 110, and the active contacts AC may be electrically connected to the first and second source/drain patterns SD1 and SD2. A gate contact GC may be formed to penetrate the second interlayer insulating layer 120 and the gate capping pattern GP, and the gate contact GC may be electrically connected to the gate electrode GE.

The formation of each of the active contact AC and the gate contact GC may include forming a barrier pattern BM, and forming a conductive pattern FM on the barrier pattern BM. The barrier pattern BM may be conformally formed and may include a metal layer/a metal nitride layer. The conductive pattern FM may include a low-resistance metal.

Isolation structures DB may be formed at a first boundary BD1 and a second boundary BD2 of the first single height cell SHC1, respectively. The isolation structure DB may penetrate the second interlayer insulating layer 120 and the gate electrode GE and may extend into the active pattern AP1 or AP2. The isolation structure DB may include an insulating material such as silicon oxide or silicon nitride.

A third interlayer insulating layer 130 may be formed on the active contacts AC and the gate contacts GC. A first metal layer M1 may be formed in the third interlayer insulating layer 130. A fourth interlayer insulating layer 140 may be formed on the third interlayer insulating layer 130. A second metal layer M2 may be formed in the fourth interlayer insulating layer 140.

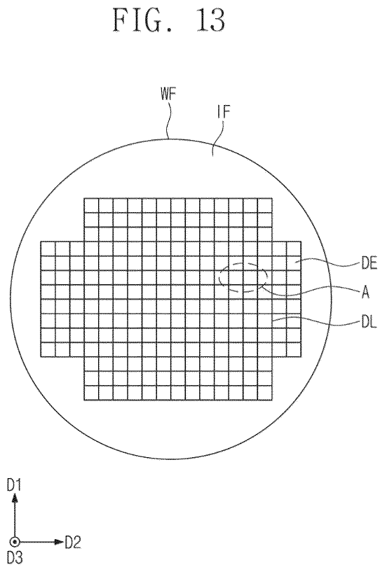

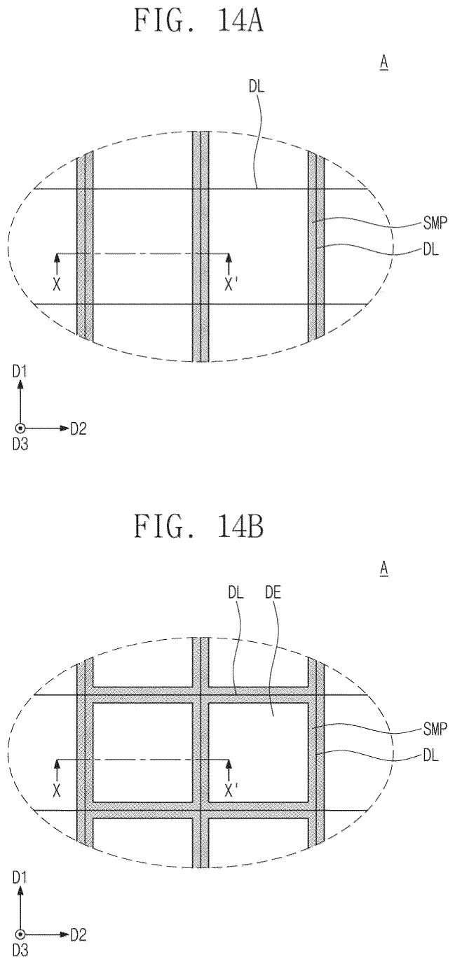

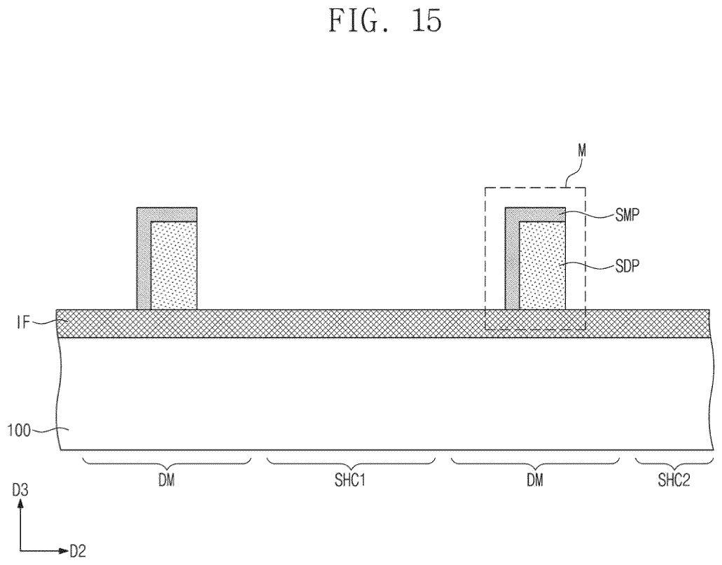

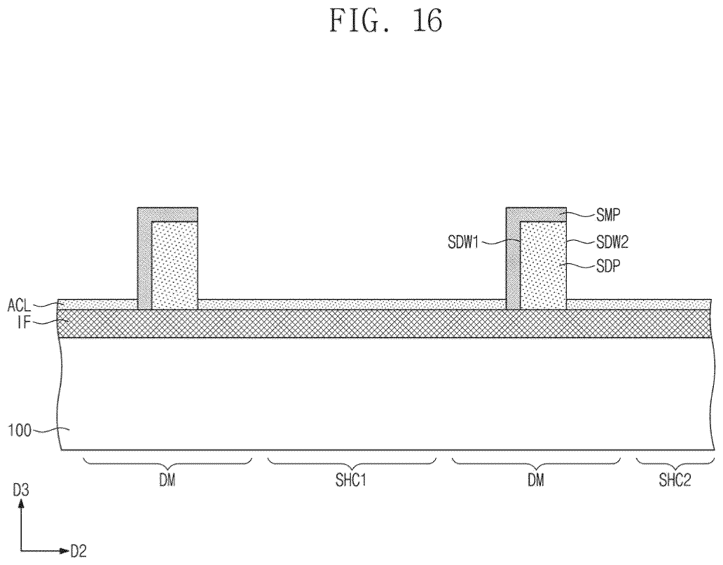

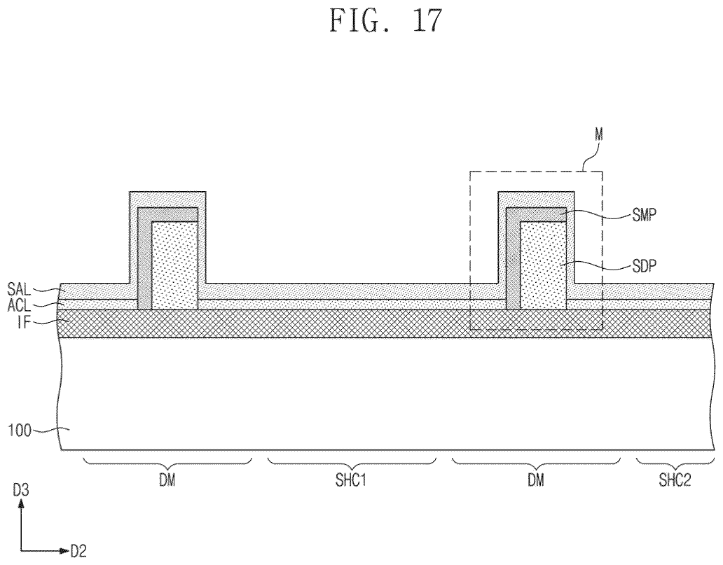

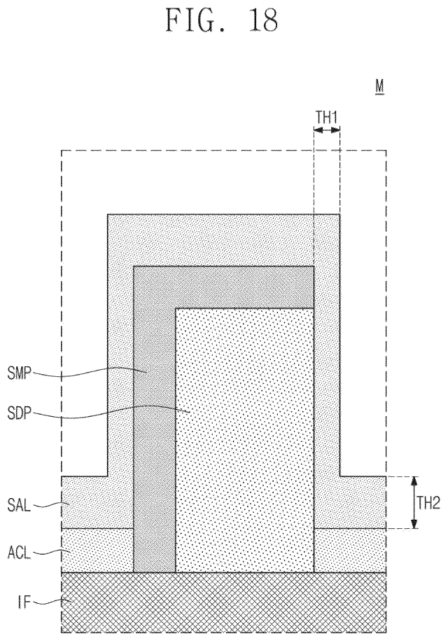

FIGS. 13 to 21 are diagrams illustrating a method of forming a structure of FIG. 7A according to one or more example embodiments. Hereinafter, the method of forming the stack pattern STP will be described in more detail with reference to FIGS. 13 to 21. FIGS. 15, 16, 17, 19, 20 and 21 are cross-sectional views taken along a line X-X′ of FIG. 14A. FIG. 18 is an enlarged view of a region ‘M’ of FIG. 17.

Referring to FIG. 13, the insulating pattern IF may be formed on a wafer substrate WF. The insulating pattern IF may be formed by depositing an insulating material on an entire top surface of the wafer substrate WF. Die lines DL may be spaced apart from each other and may be arranged in the first direction D1 and the second direction D2. The die lines DL arranged in the first direction D1 may intersect the die lines DL arranged in the second direction D2. A semiconductor die region DE may be defined by the die lines DL.

FIGS. 14A and 14B are enlarged views of a region ‘A’ of FIG. 13. FIG. 15 is a cross-sectional view taken along a line X-X′ of FIG. 14A. Referring to FIGS. 14A and 15, the seed pattern SDP and the seed mask pattern SMP may be formed on each of the die lines DL extending in the first direction D1. For example, the seed mask pattern SMP may have a line shape or bar shape extending in the first direction D1. As described with reference to FIGS. 5A to 5E, the seed mask pattern SMP may cover the top surface and one sidewall of the seed pattern SDP. A length of the seed pattern SDP may be less than a length of the semiconductor die region DE. The seed pattern SDP and the seed mask pattern SMP may be formed between adjacent die lines DL. For example, the seed pattern SDP and the seed mask pattern SMP may be formed on the semiconductor die region DE.

Referring to FIG. 14B, the seed mask pattern SMP may be formed on the die lines DL extending in the second direction D2 as well as the die line DL extending in the first direction D1. The seed pattern SDP may not be formed on the die lines DL extending in the second direction D2. The seed mask pattern SMP extending in the second direction D2 may be formed to grow the active layer ACL in a desired region when the active layer ACL is grown from the seed pattern SDP.

For example, the formation of the seed pattern SDP may include forming a seed layer on an entire top surface of the insulating pattern IF, forming a mask pattern on the seed layer, and patterning the seed layer using the mask pattern as an etch mask.

The formation of the seed mask pattern SMP may include conformally forming an insulating layer on the seed pattern SDP, forming a mask pattern on the insulating layer, and patterning the insulating layer using the mask pattern as an etch mask.

Referring to FIG. 16, the active layer ACL may be formed to be grown from the seed pattern SDP. The first sidewall SDW1 and the top surface of the seed pattern SDP may be covered by the seed mask pattern SMP, and thus the active layer ACL may not be grown from the first sidewall SDW1 and the top surface of the seed pattern SDP. The active layer ACL may be grown from the second sidewall SDW2 of the seed pattern SDP in the second direction D2. In other words, the active layer ACL may be grown from the seed pattern SDP in a single direction. Thus, the active layer ACL may be formed as a single layer on the insulating pattern IF. The active layer ACL may be a single-crystalline layer.

Referring to FIG. 17, the sacrificial layer SAL may be conformally formed on an entire top surface of the substrate 100. The sacrificial layer SAL may be formed on the active layer ACL, the seed pattern SDP and the seed mask pattern SMP. The sacrificial layer SAL may include a material having an etch selectivity with respect to the active layer ACL. The sacrificial layer SAL may be formed using a deposition process such as a physical vapor deposition (PVD) process, a CVD process and/or an atomic layer deposition (ALD) process.

FIG. 18 is the enlarged view of the region ‘M’ of FIG. 17. Referring to FIG. 18, the sacrificial layer SAL may include a portion covering the active layer ACL, a portion covering the sidewall of the seed pattern SDP and a sidewall of the seed mask pattern SMP, and a portion covering a top surface of the seed mask pattern SMP. The thickness TH2 of the portion covering the active layer ACL may be greater than a thickness TH1 of the portion covering the sidewall of the seed pattern SDP. By varying the thickness as shown in FIG. 18, embodiments may completely remove the portion covering the sidewall of the seed pattern SDP and the sidewall of the seed mask pattern SMP in the process of etching the sacrificial layer SAL (e.g., FIG. 19). In other words, the thickness difference (e.g., TH2>TH1) may be realized to leave the portion of the sacrificial layer SAL on the active layer ACL.

Conditions of the deposition process of forming the sacrificial layer SAL may be adjusted to minimize the thickness TH1 of the portion covering the sidewall of the seed pattern SDP and the sidewall of the seed mask pattern SMP. The thickness TH2 of the sacrificial layer SAL covering the active layer ACL may be greater than a thickness of the active layer ACL.

Referring to FIG. 19, the sacrificial layer SAL covering the sidewall of the seed pattern SDP and the sidewall of the seed mask pattern SMP may be removed by an etching process to form the sacrificial layer SAL. The thickness of the sacrificial layer SAL covering the active layer ACL and the thickness of the sacrificial layer SAL covering the top surface of the seed mask pattern SMP may be reduced by the etching process. The sacrificial layer SAL on the seed mask pattern SMP may not be completely removed.

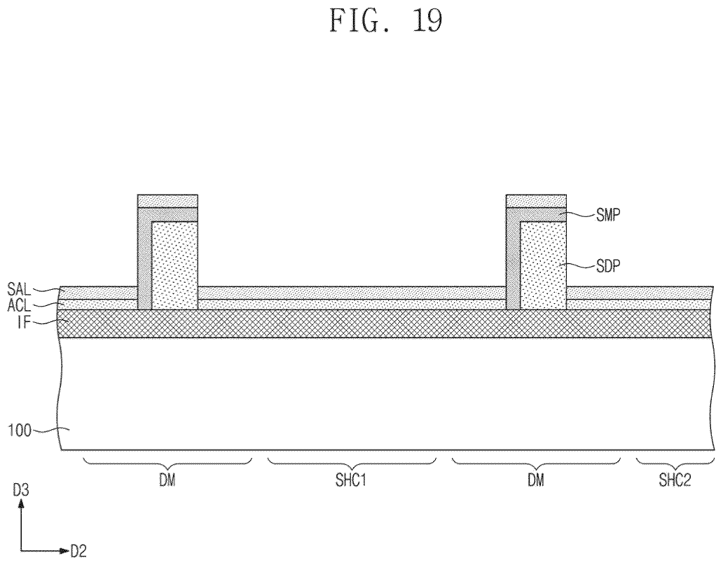

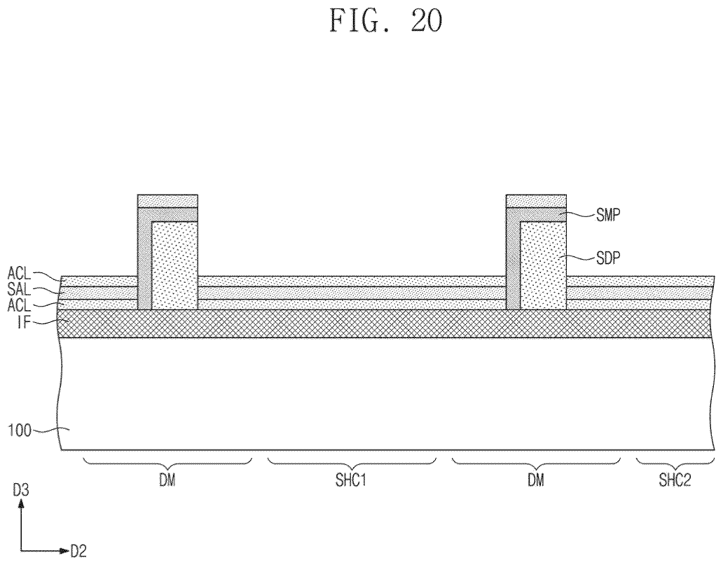

Referring to FIG. 20, the active layer ACL may be grown from the seed pattern SDP and thus may be formed on the sacrificial layer SAL. A method of forming the active layer ACL of FIG. 20 may be the same as the method of forming the active layer ACL of FIG. 16.

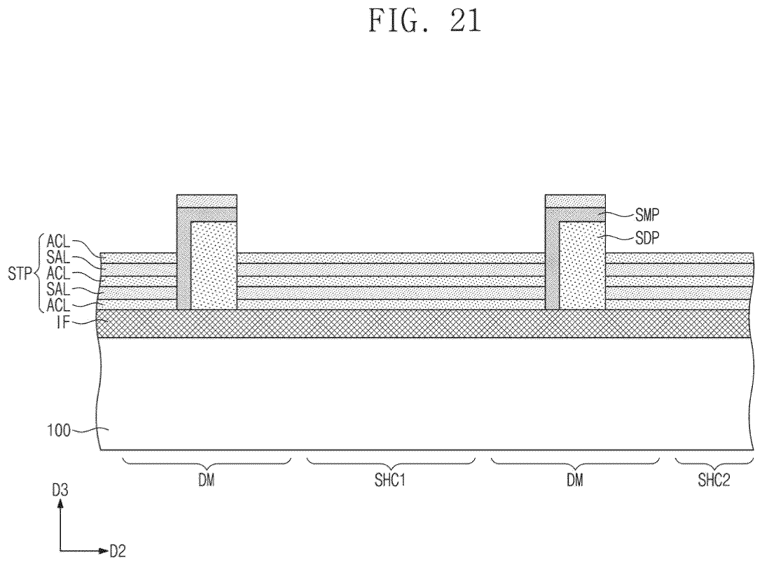

Referring to FIG. 21, the processes of FIGS. 16 to 19 may be repeated to form the active layers ACL and the sacrificial layers SAL which are alternately stacked on the substrate 100.

According to the semiconductor manufacturing method of example embodiments, the active layer ACL may be formed from the seed pattern SDP. Since the top surface and one sidewall of the seed pattern SDP are covered by the seed mask pattern SMP, the active layer ACL may be grown from the seed pattern SDP in the single direction. Since the active layer ACL is grown in the single direction, the active layer ACL may be thinly formed as the single-crystalline layer and may be uniformly formed in a desired region. In addition, the stack pattern STP may be formed without an additional photolithography process in the process of growing the active layer ACL from the seed pattern SDP and the process of forming the sacrificial layer SAL. As a result, electrical characteristics of the semiconductor device may be improved.

Hereinafter, various embodiments of a method of manufacturing a semiconductor device according to example embodiments will be described. In the following embodiments, the descriptions to the same technical features as mentioned above with reference to FIGS. 15 to 21 will be omitted and differences between the following embodiments and the above embodiments will be mainly described, for the purpose of ease and convenience in explanation.

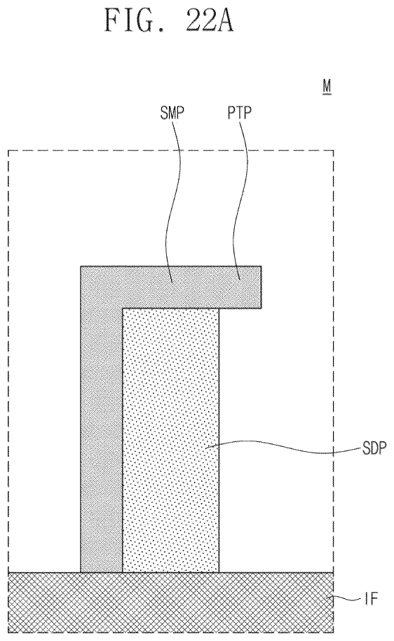

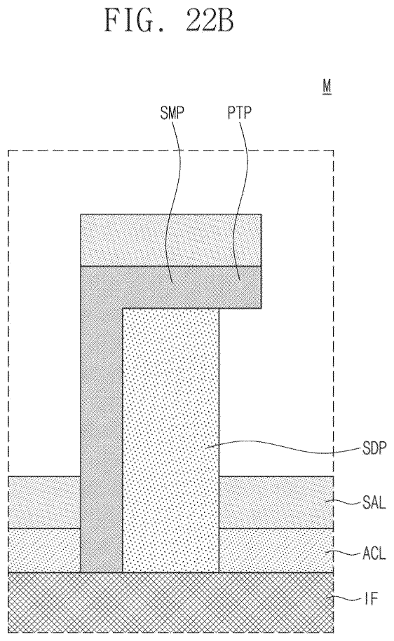

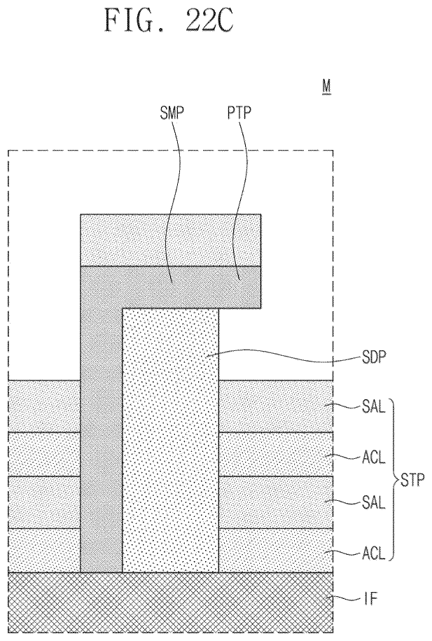

FIGS. 22A, 22B, and 22C are enlarged views of a region ‘M’ of FIG. 15 according to one or more example embodiments.

FIGS. 22A, 22B, and 22C are views illustrating a method of forming a structure of FIG. 6B. Referring to FIG. 22A, the seed mask pattern SMP may include a protrusion PTP which extends along the top surface of the seed pattern SDP and protrudes in the second direction D2.

Referring to FIGS. 22B and 22C, the sacrificial layer SAL may be formed on the insulating pattern IF. Due to the protrusion PTP of the seed mask pattern SMP, the sacrificial layer SAL may not be deposited on the sidewall of the seed pattern SDP and the sidewall of the seed mask pattern SMP. Thus, the stack pattern STP may be formed without an additional etching process of the sacrificial layer SAL.

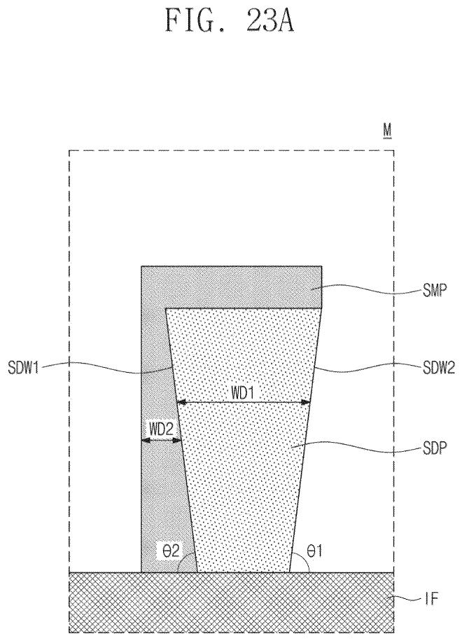

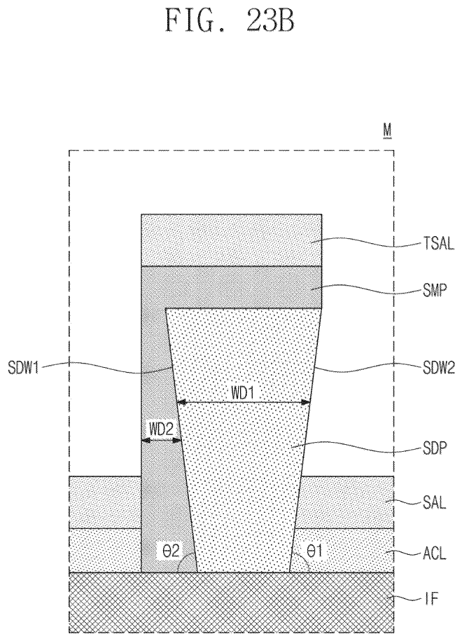

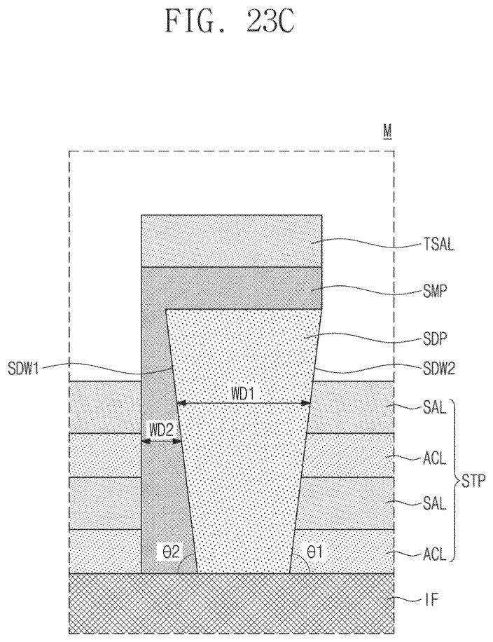

FIGS. 23A to 23C are diagrams illustrating a method of forming a structure of FIG. 6C according to one or more example embodiments. Referring to FIG. 23A, a first angle θ1 between the second sidewall SDW2 of the seed pattern SDP and the top surface of the insulating pattern IF may be an acute angle. A second angle θ2 between the first sidewall SDW1 of the seed pattern SDP and the top surface of the insulating pattern IF may be an acute angle. A width WD1 of the seed pattern SDP in the second direction D2 may progressively decrease toward the insulating pattern IF. A width WD2 of the seed mask pattern SMP covering the first sidewall SDW1 of the seed pattern SDP may progressively increase toward the insulating pattern IF.

Referring to FIGS. 23B and 23C, the sacrificial layer SAL may be formed on the insulating pattern IF. Since the second sidewall SDW2 of the seed pattern SDP forms the acute angle with the top surface of the insulating pattern IF, the sacrificial layer SAL may not be deposited on the second sidewall SDW2 of the seed pattern SDP. Thus, the stack pattern STP may be formed without an additional etching process of the sacrificial layer SAL.

The semiconductor device according to one or more example embodiments may include the insulating pattern on the dummy region, and the seed pattern and the seed mask pattern on the insulating pattern. The seed mask pattern may cover the top surface and one sidewall of the seed pattern. The channel pattern may be grown from the sidewall of the seed pattern, which is exposed by the seed mask pattern. Since the channel pattern is grown from the seed pattern in the single direction due to the seed mask pattern, the channel pattern may be a single-crystalline layer.

In addition, in the method of manufacturing a semiconductor device according to one or more example embodiments, the seed pattern and the seed mask pattern may be formed on the substrate, and thus the active layer may be formed on a desired region. As a result, the electrical characteristics of the semiconductor device may be improved.

Each of the embodiments provided in the above description is not excluded from being associated with one or more features of another example or another embodiment also provided herein or not provided herein but consistent with the disclosure

While certain example embodiments of the disclosure have been particularly shown and described, it will be understood that various changes in form and details may be made therein without departing from the spirit and scope of the following claims.

What is claimed is:

1. A semiconductor device comprising:
a substrate;
a first device region on the substrate;
a second device region on the substrate and spaced apart from the first device region in a first direction;
a first dummy region between the first device region and the second device region; and
an insulating pattern in the first device region, the second device region, and the first dummy region,
wherein the first dummy region comprises:
a seed pattern on the insulating pattern; and
a seed mask pattern at least partially covering a top surface of the seed pattern and extending from the top surface of the seed pattern along a first sidewall of the seed pattern,
wherein the insulating pattern in the first dummy region is on the substrate, and
wherein the seed pattern comprises a transition metal dichalcogenide.

2. The semiconductor device of claim 1, wherein each of the first device region and the second device region comprises:
an active pattern on the substrate, wherein the insulating pattern in the first device region and the second device region is on respective active patterns of the first device region and the second device region;
source/drain patterns on the insulating pattern;
channel patterns on the insulating pattern and connected to the source/drain patterns, each of the channel patterns comprising a plurality of semiconductor patterns vertically stacked and spaced apart from each other;
gate electrodes respectively on the channel patterns, the gate electrodes extending parallel to each other in a second direction that is perpendicular to the first direction; and
active contacts respectively connected to the source/drain patterns, and
wherein the plurality of semiconductor patterns comprise a material that is the same as a material of the seed pattern.

3. The semiconductor device of claim 2, wherein a bottom surface of a lowermost semiconductor pattern of the plurality of semiconductor pattern directly contacts a top surface of the insulating pattern.

4. The semiconductor device of claim 2, wherein the seed pattern comprises a second sidewall exposed by the seed mask pattern,
wherein the second sidewall is adjacent to the first device region,
wherein the first sidewall is adjacent to the second device region, and
wherein a thickness of each of the plurality of semiconductor patterns of the first device region progressively increases toward the second sidewall.

5. The semiconductor device of claim 2, wherein the top surface of the seed pattern is at a level that is higher than a level of a top surface of an uppermost semiconductor pattern of the plurality of semiconductor patterns.

6. The semiconductor device of claim 2, wherein each of the plurality of semiconductor patterns comprises a single-crystalline transition metal dichalcogenide.

7. The semiconductor device of claim 1, wherein the seed mask pattern comprises an upper portion at least partially covering the top surface of the seed pattern,
wherein a width of the upper portion is greater than a width of the seed pattern, and
wherein the upper portion comprises a protrusion extending along the top surface of the seed pattern and protruding in the first direction.

8. The semiconductor device of claim 1, wherein the seed pattern comprises a second sidewall exposed by the seed mask pattern, and
wherein the second sidewall forms an acute angle with a top surface of the insulating pattern.

9. The semiconductor device of claim 1, wherein a width of the seed pattern progressively decreases toward the insulating pattern.

10. The semiconductor device of claim 1, wherein the seed mask pattern comprises a lower portion at least partially covering the first sidewall of the seed pattern, and
wherein a width of the lower portion of the seed mask pattern progressively increases toward the insulating pattern.

11. A semiconductor device comprising:
a substrate;
a first logic cell on the substrate;
a second logic cell on the substrate and spaced apart from the first logic cell in a first direction; and
a dummy region between the first logic cell and the second logic cell,
wherein the first logic cell comprises:
a first source/drain pattern; and
a first channel pattern connected to the first source/drain pattern,
wherein the first channel pattern comprises a plurality of semiconductor patterns vertically stacked and spaced apart from each other,
wherein the dummy region comprises:
an insulating pattern on the substrate;
a seed pattern on the insulating pattern; and
a seed mask pattern at least partially covering a top surface of the seed pattern and a first sidewall of the seed pattern, and
wherein the top surface of the seed pattern is a level that is higher than a level of a top surface of an uppermost semiconductor pattern of the plurality of semiconductor patterns.

12. The semiconductor device of claim 11, wherein the seed pattern comprises a transition metal dichalcogenide.

13. The semiconductor device of claim 11, wherein each of the plurality of semiconductor patterns comprises a material that is the same as a material of the seed pattern.

14. The semiconductor device of claim 11, wherein a bottom surface of a lowermost semiconductor pattern of the plurality of semiconductor patterns directly contacts a top surface of the insulating pattern.

15. The semiconductor device of claim 11, wherein the seed pattern comprises a second sidewall exposed by the seed mask pattern,
wherein the second sidewall is adjacent to the first logic cell,
wherein the first sidewall is adjacent to the second logic cell, and
wherein a thickness of each of the plurality of semiconductor patterns of the first logic cell progressively increases toward the second sidewall.

16. A semiconductor device comprising:
a substrate;
a first device region on the substrate;
a second device region on the substrate and spaced apart from the first device region in a first direction;
a first dummy region between the first device region and the second device region; and
an insulating pattern in the first device region, the second device region and the first dummy region,
wherein the first dummy region comprises:
a seed pattern provided on the insulating pattern; and
a seed mask pattern at least partially covering a top surface of the seed pattern and extending from the top surface of the seed pattern along a first sidewall of the seed pattern,
wherein each of the first device region and the second device region comprises:
an active pattern on the substrate, wherein the insulating pattern in the first device region and the second device region is on respective active patterns of the first device region and the second device region;
source/drain patterns on the insulating pattern;
channel patterns on the insulating pattern and connected to the source/drain patterns, each of the channel patterns comprising a plurality of semiconductor patterns vertically stacked and spaced apart from each other;
gate electrodes respectively on the channel patterns, the gate electrodes extending parallel to each other in a second direction that is perpendicular to the first direction; and
active contacts respectively connected to the source/drain patterns,
wherein the plurality of semiconductor patterns comprise a material that is the same as a material of the seed pattern,
wherein the seed pattern comprises a second sidewall opposite the first sidewall and that is exposed by the seed mask pattern, and
wherein the second sidewall forms an acute angle with a top surface of the insulating pattern.

17. The semiconductor device of claim 16, wherein the seed pattern comprises a transition metal dichalcogenide.

18. The semiconductor device of claim 16, wherein a width of the seed pattern progressively decreases toward the insulating pattern.

19. The semiconductor device of claim 16, wherein the seed mask pattern comprises a lower portion at least partially covering the first sidewall of the seed pattern, and
wherein a width of the lower portion progressively increases toward the insulating pattern.

20. The semiconductor device of claim 16, wherein the top surface of the seed pattern is at a level that is higher than a level of a top surface of an uppermost semiconductor pattern of the plurality of semiconductor patterns.
